(19) United States
(12) Patent Application Publication
(10) Pub. No.: US 2009/0295774 A1
(43) Pub. Date: Dec. 3, 2009

(54) Semiconductor integrated circuit having internal voltage generating circuit

(75) Inventor: Toshiharu Okamoto, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kanagawa (JP)

(21) Appl. No.: 12/453,876

(22) Filed: May 26, 2009

(30) Foreign Application Priority Data
May 27, 2008 (JP) 2008-137606

(51) Int. Cl. G09G 5/00; G11C 5/14; G11C 8/00; G09G 3/36

(52) U.S. Cl. 345/211; 365/226; 365/230.03; 345/87

(57) ABSTRACT

A semiconductor integrated circuit device, includes: a RAM (Random Access Memory) circuit; and an internal power source circuit. The RAM circuit includes a plurality of RAM circuit blocks. The internal power source circuit supplies a voltage a selection RAM block selected from the plurality of RAM circuit blocks, wherein the voltage corresponds to an arrangement place of the selection RAM circuit block.

### INCORPORATED BY REFERENCE

This application is based upon and claims the benefit of priority from Japanese patent application No. 2008-137606 filed on May 27, 2008, the disclosure of which is incorporated herein in its entirety by reference.

### BACKGROUND OF THE INVENTION

1. Field of the Invention

The present invention relates to a semiconductor integrated circuit device and more particularly relates to a semiconductor integrated circuit device having an internal voltage generating circuit, and a control method of the same.

2. Description of Related Art

As a semiconductor integrated circuit device, a liquid crystal display driver IC (hereafter, referred to as an LCD driver) is known for driving a liquid crystal display panel (hereafter, referred to as an LCD panel). The LCD driver is required to be arranged in the periphery of the LCD panel. For this reason, a chip of the LCD driver is required to have the long and thin shape in which an aspect ratio is unbalanced, as compared with the chip of the semiconductor integrated circuit generally imagined.

The LCD driver includes a logic circuit, a high voltage driver circuit, an internal power source circuit for generating an internal voltage, and a RAM (Random Access Memory) circuit. The RAM circuit transiently holds pixel control information to control the LCD panel by using the internal voltage. The logic circuit, the high voltage driver circuit, the internal power source circuit and the RAM circuit are arranged in the arrangement region of the chip.

An occupation rate of a region, in which the RAM circuit is arranged, is high with respect to the chip area (layout region) of the LCD driver. The RAM circuit is generally divided into a plurality of RAM circuit blocks in capacity units, for which the trade-off between the performance of the RAM itself and the cost is taken into consideration. The plurality of RAM circuit blocks are connected to power source nodes (which will be described later) different from each other. Each of the plurality of RAM circuit blocks includes a cell array matrix having RAM cells, an address circuit selecting a RAM cell based on an address, and a sense amplifying circuit reading a data from the selected RAM cell. When the LCD driver is designed, since the RAM circuit is divided into the plurality of RAM circuit blocks, the number of the RAM circuit blocks installed in the LCD driver can be softly selected, on the basis of the RAM capacity required by the LCD driver.

When the RAM circuit block is installed in the LCD driver, there are the following problems.

The RAM circuit block is the block whose area is relatively large, with respect to the chip size of the LCD driver. The chip shape of the LCD driver is restricted to be long and thin. Under such a restriction, since there are not so many candidate regions where the plurality of RAM circuit blocks can be arranged, the plurality of RAM circuit blocks is typically arrayed in line on the chip. Thus, the internal power source wirings for supplying the internal power source voltages to those RAM circuit blocks are also long. For this reason, the parasitic resistance of the internal power source wiring is increased. Hence, this leads to a problem of the non-negligible drop of the internal power source voltage supplied to the RAM circuit block when the RAM circuit block is operated.

The access speed of the RAM circuit block is proportional to the internal power source voltage supplied to its RAM circuit block. When the internal power source voltage is high, the access speed is fast. On the other hand, when the internal power source voltage is low, the access speed is slow.

In the LCD driver including the plurality of RAM circuit blocks, when the access speed differences among those of RAM circuit blocks are large, this results in the trouble in which the logic circuit for capturing output data from those RAM circuit blocks cannot operate in the right timings. For this reason, the internal power source voltages supplied to the respective RAM circuit blocks is required to be designed to be approximately equal.

Also, since the plurality of LCD drivers are arranged in the periphery of the LCD panel, the chip size and operation current of each LCD driver are required to be designed as small as possible, from the viewpoint of the lower cost and lower power of the entire liquid crystal display system.

A technique described in Japanese Laid-Open Patent Application JP-P 2006-318380A (corresponding US Patent Application US2006259800 (A1)) will be described below.

The circuit system described in JP-P 2006-318380A includes a plurality of circuit units, a power source for supplying a plurality of different voltages, a plurality of power source selecting circuits, and a control circuit. The plurality of power source selecting circuits is provided correspondingly to the plurality of circuit units. The plurality of power source selecting circuits selects the voltages supplied to the respective circuit units from the plurality of different voltages. The control circuit controls the plurality of power source selecting circuits so that the voltages supplied to the respective circuit units are selected, on the basis of the respective operation states of the plurality of circuit units. Each circuit unit uses the voltage selected by the power source selecting circuit as the voltage supplied by the internal power source.

A technique described in Japanese Laid Open Patent Application JP-A-Heisei, 05-266224 will be described below.

A semiconductor integrated circuit described in JP-A-Heisei, 05-266224 includes a voltage reducing circuit reducing an external power source voltage, and a plurality of functional modules whose operation voltages are the voltages generated by this voltage reducing circuit. This semiconductor integrated circuit includes the dedicated voltage reducing circuit for each of the functional modules, in order to relax an undesirable voltage reduction generated in the parasitic resistance of a power source wiring.

We have now discovered the following facts.

As mentioned above, since the LCD driver has the restriction of the chip shape (long and thin), the plurality of RAM circuit blocks are arranged in line, and the internal power source wirings for supplying the internal power source voltages to those RAM circuit blocks are long. The parasitic resistance of the internal power source wiring depends on the distance between the internal power source circuit and each of the RAM circuit blocks. When a certain RAM circuit block is arranged at a place away from the internal power source circuit, the internal power source voltage supplied to the certain RAM circuit block is dropped by the operation current of the RAM circuit block and the parasitic resistance of the internal power source wiring. Thus, a problem is caused in which the access speed of the RAM circuit block is deteriorated.

For example, let us suppose that there are n (n is an integer) number of the RAM circuit blocks, and the n number of the RAM circuit blocks are arranged in an order between the RAM circuit block closest to the internal power source circuit and the RAM circuit block farthest from the internal power source circuit, in the first to n-th RAM circuit blocks. The internal power source wiring is connected to the internal power source circuit, and the n number of the RAM circuit blocks are connected to the internal power source wiring in parallel. In the internal power source wiring, n number of parasitic resistances are generated as the parasitic resistances corresponding to the arrangement places of the n number of the RAM circuit blocks, respectively. That is, the n number of the RAM circuit blocks are connected through connection nodes to the internal power source wiring, respectively, and the n number of the parasitic resistances corresponding to the n number of the RAM circuit blocks are generated between the connection nodes of the internal power source wiring, respectively. In this case, the n number of the RAM circuit blocks are assumed to be arranged in the order between the RAM circuit block having the smallest parasitic resistance and the RAM circuit block having the greatest parasitic resistance. Here, in order to simplify the explanation, all of the resistance values of the n number of the parasitic resistances are assumed to be equal. Also, each of the operation currents of the n number of the RAM circuit blocks is defined as Iact, and the n number of the parasitic resistances are defined as R1, R2, R3, - - - , Rn−1 and Rn, and the internal power source voltage supplied to the internal power source wiring by the internal power source circuit is defined as VINT1.

In this case, an internal power source voltage VINT1far applied to the n-th RAM circuit block is represented by the following equation.

VINT1far=VINT1−Iact×(R1+R2+R3+ - - - +Rn-1+Rn)

Also, an internal power source voltage VINT1near applied to the first RAM circuit block is represented by the following equation.

VINT1near=VINT1−Iact×R1

Thus, a difference ΔV between the internal power source voltages of the n-th RAM circuit block and the first RAM circuit block is represented as follows.

$$\begin{matrix}Δ V = VINT 1 far - VINT 1 near \\ = Iact \times ( R 2 + R 3 + … + Rn - 1 + Rn )\end{matrix}$$

Therefore, the drop of the internal power source voltage proportional to the difference between the parasitic resistances is generated.

As mentioned above, the access speed of the RAM circuit block is proportional to the internal power source voltage applied to the RAM circuit block. When the internal power source voltage is high, the access speed is fast, and when the internal power source voltage is low, the access speed is slow. Thus, the internal power source voltage applied to the RAM circuit block currently in operation is dropped by the parasitic resistance of the internal power source wiring and the operation current of the RAM circuit block. This causes the voltage drop amount to be varied, depending on the arrangement place of the RAM circuit block. Hence, the access speed is varied, which results in the trouble in which the logic circuit for capturing output data from those RAM circuit blocks cannot operate in the right timings, depending on the variation amount.

In order to solve such troubles, it may be considered to decrease the parasitic resistance of the internal power source wiring. However, when there is the restriction of the long and thin chip shape such as the LCD driver, it is difficult to employ the layout in which the internal power source wiring is made thick or wide in the limited region. Tentatively, if the layout of the internal power source wirings is optimized only from the viewpoint of the minimization in the parasitic resistance of the internal power source wiring, the chip size of the LCD driver is made larger than before. Thus, there is a possibility that other troubles occurs, such as manufacturing cost increase and size mismatching between the LCD driver and the LCD panel.

As for such troubles, according to the technique described in JP-P 2006-318380A, when the RAM circuit block is operated, the connection is switched to the different internal power source wiring, which is set to the higher internal power source voltage than before, by the internal power source selecting circuit. Thus, the decreasing of the access speed, which is caused by the drop in the internal power source voltage that results from the parasitic resistance of the internal power source wiring, is minimized.

However, in the technique described in JP-P 2006-318380A, the respective RAM circuit blocks require the respective internal power source selecting circuits. Since the respective internal power source selecting circuits are combined with the respective RAM circuit blocks, the circuit scale is enlarged, which results in a problem that the chip size is enlarged. Also, since the internal power source circuit for generating the plurality of internal power source voltages is required, the scale of the internal power source circuit is enlarged, which becomes a factor that the chip size is enlarged. Also, in order to supply the plurality of generated internal power source voltages to the RAM circuit blocks, the plurality of internal power source wirings are arranged, which also becomes a factor that the layout area of the internal power source wirings is increased.

According to the technique described in JP-A-Heisei, 05-266224, each of the RAM circuit blocks has its own internal power source circuit. Thus, the drop in the internal power source voltage that is caused by the parasitic resistance of the internal power source wiring is not generated.

However, the technique described in JP-A-Heisei, 05-266224 has a problem that, since the internal power source circuit is arranged for each RAM circuit block, the chip size is enlarged. Also, the number of the internal power source circuits is increased, which results in a problem that the operation current of the entire LCD driver is increased.

### SUMMARY

The present invention seeks to solve one or more of the above problems, or to improve upon those problems at least in part.

In one embodiment, a semiconductor integrated circuit device, includes: a RAM (Random Access Memory) circuit configured to include a plurality of RAM circuit blocks; and an internal power source circuit configured to supply a voltage to a selection RAM block selected from the plurality of RAM circuit blocks, wherein the voltage corresponds to an arrangement place of the selection RAM circuit block.

In another embodiment, a liquid crystal display driver for driving a liquid crystal display panel, includes: a RAM (Random Access Memory) circuit configured to include a plurality of RAM circuit blocks; and an internal power source circuit configured to supply a voltage to a selection RAM block selected from the plurality of RAM circuit blocks, wherein the voltage corresponds to an arrangement place of the selection RAM circuit block.

According to the semiconductor integrated circuit device of the present invention, a selection RAM circuit block is selected. At this time, a voltage drop arises in which a drop amount of a voltage (a drop voltage) is determined based on a parasitic resistance of an internal power source wiring between an internal power source circuit and the selection RAM circuit block and an operation current of the selection RAM circuit block. The parasitic resistance and the drop voltage are determined based on an arrangement place of the selection RAM circuit block. Thus, the internal power source circuit supplies the voltage based on the arrangement place of the selection RAM circuit block, as an output voltage, to the selection RAM circuit block. Consequently, according to the semiconductor integrated circuit device of the present invention, as its effect, the undesirable drop is not generated in the selection RAM circuit block currently in operation. Thus, performances of RAM circuit blocks are not deteriorated. That is, even if an optimal layout cannot be designed from the viewpoint of reducing the resistance of the internal power source wiring because the restriction on the chip shape is severe, the output voltage at which access speed is not reduced can be supplied to the selection RAM circuit block located away from the internal power source circuit.

Also, according to the semiconductor integrated circuit device of the present invention, since the output level (the output voltage) of the internal power source circuit is variably controlled only in a period when the selection RAM circuit block is operated, the increase in the operation current of the internal power source circuit can be suppressed to the necessary minimum. Also, according to the semiconductor integrated circuit device of the present invention, the wiring width is not required to be made thick or wide beyond necessity, for the sake of the lower resistance of the internal power source wiring. Thus, the increase in the chip size can be avoided, and the cost reduction can be attained.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a view showing a configuration of the semiconductor integrated circuit device according to the first embodiment of the present invention;

FIG. 2 is a view showing a configuration example of the voltage dividing circuit and the logic circuit according to the first and second embodiments of the present invention;

FIGS. 3A and 3B are timing charts each showing a relation between the RAM circuit block activation signals, the output voltage of the internal power source circuit and the voltages applied to the power source ports, as an operation of the semiconductor integrated circuit device according to the first embodiment of the present invention;

FIG. 4 is a view showing a configuration of a variation example 1 of the semiconductor integrated circuit device according to the first embodiment of the present invention;

FIG. 5 is a view showing a configuration of an example of the voltage dividing circuit and the logic circuit in the variation example 1 of the semiconductor integrated circuit device according to the first embodiment of the present invention;

FIG. 6 is a view showing a configuration of a variation example 2 of the semiconductor integrated circuit device according to the first embodiment of the present invention;

FIG. 7 is a view showing a configuration of an example of the voltage dividing circuit and the logic circuit in the variation example 2 of the semiconductor integrated circuit device according to the first embodiment of the present invention;

FIG. 8 is a view showing a configuration of a variation example 3 of the semiconductor integrated circuit device according to the first embodiment of the present invention;

FIG. 9 a view showing a configuration of an example of the voltage dividing circuit and the logic circuit in the variation example 3 of the semiconductor integrated circuit device according to the first embodiment of the present invention;

FIG. 10 is a graph showing a relation between an access speed of the RAM circuit block and a power source voltage applied to the RAM circuit block as an operation of the semiconductor integrated circuit device according to the second embodiment of the present invention;

FIG. 11 is a timing chart showing a relation between the RAM circuit block activation signals, the output voltage of the internal power source circuit and the voltages applied to the power source ports, as the operation of the semiconductor integrated circuit device according to the second embodiment of the present invention;

FIG. 12 is a view showing a configuration of a semiconductor integrated circuit device according to the third embodiment of the present invention;

FIGS. 13A and 13B are views showing a configuration of a variation example 1 of the semiconductor integrated circuit device according to the third embodiment of the present invention;

FIGS. 14A and 14B are views showing a configuration of a variation example 2 of the semiconductor integrated circuit device according to the third embodiment of the present invention; and

FIGS. 15A and 15B is views showing a configuration of a variation example 3 of the semiconductor integrated circuit device according to the third embodiment of the present invention.

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

The semiconductor integrated circuit device according to the embodiment of the present invention will be described below in detail with reference to the attached drawings.

### First Embodiment

### [Configuration]

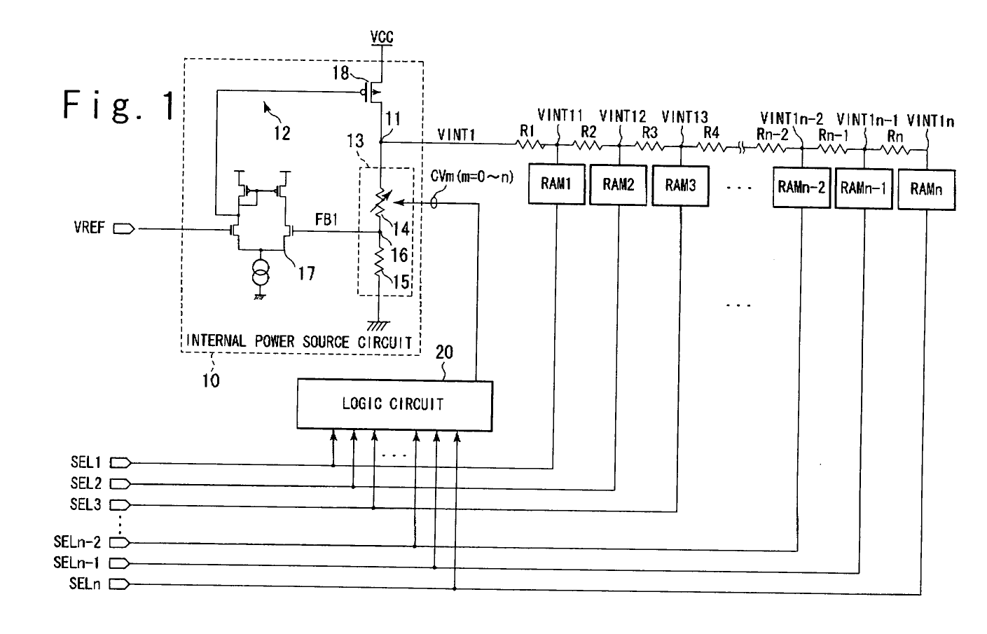

FIG. 1 is a view showing a configuration of the semiconductor integrated circuit device according to the first embodiment of the present invention. The semiconductor integrated circuit device includes a logic circuit 20, a high voltage driver circuit (not shown) for driving an LCD panel, an internal power source circuit 10 for generating an internal voltage, and a RAM (Random Access Memory) circuit. The RAM circuits transiently hold the pixel control information for controlling the LCD panel, using the internal voltage. The logic circuit 20, the high voltage driver circuit, the internal power source circuit 10 and the RAM circuit are arranged in the arrangement region of a chip.

The RAM circuit is divided into n number of RAM circuit blocks RAM1 to RAMn (n is an integer), as a plurality of RAM circuit blocks. These n number of the RAM circuit blocks RAM1 to RAMn are respectively connected to power source ports (which will be described later) different from each other. Each of the n number of the RAM circuit blocks RAM1 to RAMn includes a cell array matrix having RAM cells, an address circuit for selecting a RAM cell based on an address, and a sense amplifying circuit for reading a data from the selection RAM cell.

Here, the n number of the RAM circuit blocks RAM1 to RAMn are assumed to be arranged in the order, which starts with the RAM circuit block RAM1 closest to the internal power source circuit 10 and ends with the RAM circuit block RAMn farthest from the internal power source circuit 10. The internal power source wiring is connected to the internal power source circuit 10.

Further, the n number of the RAM circuit blocks RAM1 to RAMn are connected to the internal power source wiring in parallel. In the internal power source wiring, n number of parasitic resistances R1 to Rn arise as parasitic resistances correspondingly to the arrangement places of the n number of the RAM circuit blocks RAM1 to RAMn, respectively. That is, the n number of the RAM circuit blocks RAM1 to RAMn are connected through n number of power source ports VINT11 to VINT1n to the internal power source wiring, respectively. Then, the n number of the parasitic resistances R1 to Rn respectively corresponding to the n number of the RAM circuit blocks RAM1 to RAMn arise between the power source ports VINT11 to VINT1n of the internal power source wiring, respectively. In this case, the n number of the RAM circuit blocks RAM1 to RAMn are assumed to be arranged in the order, which starts with the RAM circuit block RAM1 corresponding to the smallest parasitic resistance R1 and ends with the RAM circuit block RAMn corresponding to the greatest parasitic resistance (R1+ - - - +Rn) Here, in order to simplify the explanation, all resistance values of the n number of the parasitic resistances R1 to Rn are assumed to be equal.

The internal power source circuit 10 is provided between a first power source (power source VCC) for supplying a voltage and a second power source (ground) whose voltage is lower than the first power source, and connected to an output node 11. The internal power source circuit 10 generates an internal power source voltage VINT1 and supplies it as an output voltage VINT1′ through the output node 11 to the internal power source wiring. This internal power source circuit 10 includes an internal power source control circuit 12 and the voltage dividing circuit 13.

The voltage dividing circuit 13 is provided between the output node 11 and the ground and includes a first resistance element 14 and a second resistance element 15, which are connected in series. The first resistance element 14 is provided between the output node 11 and a voltage division node 16, and the second resistance element 15 is provided between the voltage division node 16 and the ground. The voltage dividing circuit 13 divides the internal power source voltage VINT1 through the first resistance element 14 and the second resistance element 15 and generates a divided voltage FB1 and outputs to the voltage division node 16.

The internal power source control circuit 12 includes a differential amplifying circuit 17 and a switch 18. The differential amplifying circuit 17 includes two inputs and one output. The voltage division node 16 is connected to one input of the two inputs of the differential amplifying circuit 17, and the divided voltage FB1 is supplied thereto. A reference voltage VREF is supplied to the other input of the two inputs of the differential amplifying circuit 17. A P-type MOS transistor is used as the switch 18. The switch 18 is provided between the power source VCC and the output node 11, and connected to the output of the differential amplifying circuit 17 at a gate of the p-type MOS transistor. The switch 18 is turned on (conduction state) when a signal level of an output signal outputted from the differential amplifying circuit 17 is a low level “L”. The switch is turned off (non-conduction state) when the signal level is a high level “H”.

Here, n number of signal lines for supplying the RAM circuit block activation signals SEL1 to SELn are connected to the RAM circuit blocks RAM1 to RAMn, respectively. In addition, the n number of the signal lines are also connected to the inputs of the logic circuit 20. The output of the logic circuit 20 is connected to the first resistance element 14 of the voltage dividing circuit 13 inside the internal power source circuit 10. The logic circuit 20 supplies a voltage division control signal CVm (m is an integer, m=0 to n) which will be described later to the voltage dividing circuit 13 by using the RAM circuit block activation signals SEL1 to SELn.

For example, from a situation in which the signal levels of all of the RAM circuit block activation signals SEL1 to SELn are the low level “L”, the signal level of one RAM circuit block activation signal is switched to the high level “H”. In this embodiment, it is defined that the RAM circuit block is active when the RAM circuit block activation signal is in the high level “H”, and the RAM circuit block is inactive when the RAM circuit block activation signal is in the low level “L”. That is, when all of the RAM circuit blocks RAM1 to RAMn are in a non-selected state, one RAM circuit block (selection RAM circuit block) corresponding to the foregoing one RAM circuit block activation signal is selected from the RAM circuit blocks RAM1 to RAMn, and the selection RAM circuit block becomes active.

In the internal power source circuit 10, the voltage dividing circuit 13 divides the internal power source voltage VINT1 through the first resistance element 14 and the second resistance element 15 and generates the divided voltage FB1. The differential amplifying circuit 17 in the internal power source control circuit 12 compares the reference voltage VREF and the divided voltage FB1 outputted from the voltage dividing circuit 13. The differential amplifying circuit 17 sets the signal level of the output signal to the high level “H” so that the internal power source voltage VINT1 becomes low, if the divided voltage FB1 is higher than the reference voltage VREF. The switch 18 is turned off based on the output signal “H”. The differential amplifying circuit 17 sets the signal level of the output signal to the low level “L” so that the internal power source voltage VINT1 becomes high, if the divided voltage FB1 is lower than the reference voltage VREF. The switch 18 is turned on based on the output signal “L”. In this way, the internal power source control circuit 12 adjusts the internal power source voltage VINT1, based on the comparison result between the divided voltage FB1 and the reference voltage VREF.

As mentioned above, the divided voltage FB1 is determined by the voltage division ratio between the first resistance element 14 and the second resistance element 15. Also, the selection RAM circuit block is selected based on the RAM circuit block activation signals SEL1 to SELn. The logic circuit 20 supplies voltage division control signals CV0 to CVn, which set the voltage division ratio for the selection RAM circuit block based on the RAM circuit block activation signals SEL1 to SELn, to the voltage dividing circuit 13. This voltage division ratio is different in each of the RAM circuit blocks RAM1 to RAMn, and determined by the fact that which RAM circuit block is selected as the selection RAM circuit block from the RAM circuit blocks RAM1 to RAMn. In order to set the voltage division ratio for the selection RAM circuit block based on the voltage division control signals CV0 to CVn, the voltage dividing circuit 13 adjusts the resistance value of the first resistance element 14, and divides the internal power source voltage VINT1 through the first resistance element 14 and the second resistance element 15 and then generates the divided voltage FB1.

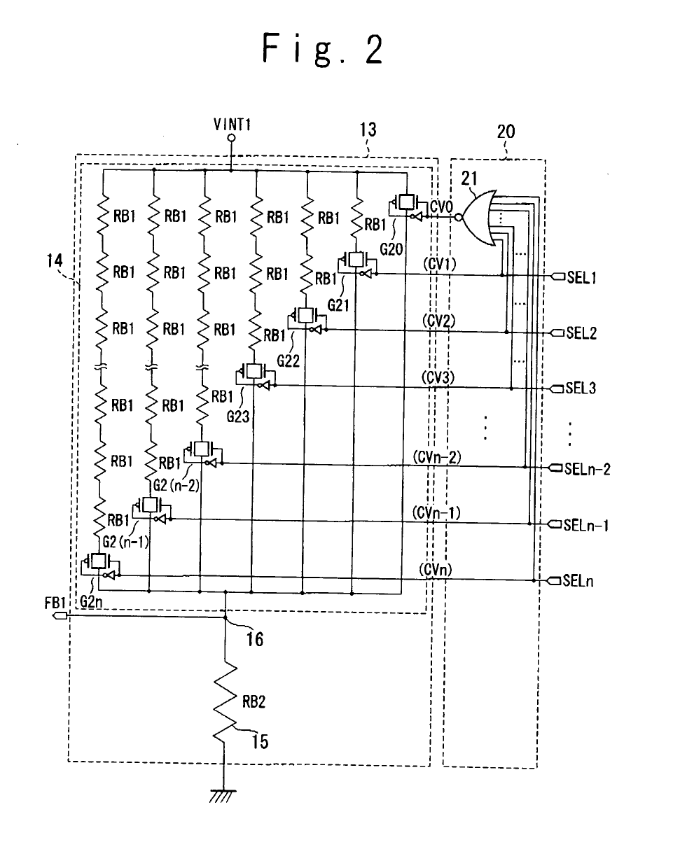

FIG. 2 is a view showing a configuration example of the voltage dividing circuit 13 and the logic circuit 20.

The logic circuit 20 includes an NOR logic gate 21. The NOR logic gate 21 receives the RAM circuit block activation signals SEL1 to SELn, carries out a NOR (negative OR) operation based on the signal levels of the RAM circuit block activation signals SEL1 to SELn, and outputs the voltage division control signal CV0 as its result to the voltage dividing circuit 13. Also, the logic circuit 20 outputs the RAM circuit block activation signals SEL1 to SELn as the voltage division control signals CV1 to CVn to the voltage dividing circuit 13, respectively.

The voltage dividing circuit 13 includes the first resistance element 14 and the second resistance element 15, as mentioned above. The first resistance element 14 is provided between the output node 11 and the voltage division node 16. The second resistance element 15 is provided between the voltage division node 16 and the ground. The first resistance element 14 includes (n+1) number of current route portions which are connected in parallel between the output node 11 and the voltage division node 16. Among the (n+1) number of the current route portions, the 0-th current route portion includes a transmission gate G20 provided between the output node 11 and the voltage division node 16. The first current route portion includes; one resistor RB1 installed between the output node 11 and the voltage division node 16; and a transmission gate G21 provided between the resistor RB1 and the voltage division node 16. The second current route portion is provided between the output node 11 and the voltage division node 16 and includes: the two first to second resistors RB1 that are connected in series; and a transmission gate G22 provided between the second resistor RB1 and the voltage division node 16. The rest is similar to the above. Then, the n-th current route portion is provided between the output node 11 and the voltage division node 16 and includes: n number of the first to n-th resistors RB1 that are connected in series; and a transmission gate G2n provided between the n-th resistor RB1 and the voltage division node 16. Each of the transmission gates G20 to G2n is provided with an N-type MOS transistor, a P-type MOS transistor, and an inverter between a gate of the N-type MOS transistor and a gate of the P-type MOS transistor. The transmission gates G20 to G2n are turned on, respectively, when the signal levels of the RAM circuit block activation signals SEL1 to SELn are the high level “H”. Among the (n+1) number of the current route portions, the first to n-th current route portions correspond to the RAM circuit blocks RAM1 to RAMn, respectively.

As mentioned above, when from the situation in which the signal levels of all the RAM circuit block activation signals SEL1 to SELn are the low level “L”, the signal level of one RAM circuit block activation signal is switched to the high level “H”, one RAM circuit block (selection RAM circuit block) corresponding to the foregoing one RAM circuit block activation signal is selected from the RAM circuit blocks RAM1 to RAMn. In this case, among the (n+1) number of the current route portions, the transmission gate of the current route portion (selection current route portion) corresponding to the selection RAM circuit block is turned on (conduction state).

### [Operation]

As the operation of the semiconductor integrated circuit device according to the first embodiment of the present invention, a case is described in which the number of the RAM circuit block currently in operation is one, in order to simplify the explanation. Here, the operation current of one RAM circuit block is defined as Iact.

At first, a case is described in which the RAM circuit block RAM1 closest to the internal power source circuit 10 is selected.

When all the signal levels of the RAM circuit block activation signals SEL1 to SELn are the low level “L”, the signal level of the voltage division control signal CV0 is set to the high level “H” by the NOR logic gate 21 inside the logic circuit 20. For this reason, in the first resistance element 14 of the voltage dividing circuit 13 in the internal power source circuit 10, the transmission gate G20 of the 0-th current route portion is in conduction state. Since the signal levels of the other voltage division control signals CV1 to CVm are the low level “L”, the transmission gates G21 to G2n are in non-conduction state. At this time, as the divided voltage FB1, the internal power source voltage VINT1 is supplied to the voltage division node 16. Thus, when the RAM circuit block is not selected, the internal power source control circuit 12 in the internal power source circuit 10 sets, as its output voltage VINT1′, the internal power source voltage VINT1 to the same voltage as the reference voltage VREF.

Next, in order to select the RAM circuit block RAM1, the signal level of the RAM circuit block activation signal SEL1 is switched to the high level “H”. At this time, the RAM circuit block RAM1 is made active. Also, by the NOR logic gate 21 inside the logic circuit 20, the signal level of the voltage division control signal CV0 is switched to the low level “L”. For this reason, in the first resistance element 14 of the voltage dividing circuit 13 in the internal power source circuit 10, the transmission gate G20 of the 0-th current route portion is turned off. Since the signal level of the RAM circuit block activation signal SEL1 is the high level “H”, the transmission gate G21 of the first current route portion is turned on. The transmission gates G22 to G2n are in non-conduction state. At this time, the voltage dividing circuit 13 is switched to the voltage division ratio determined by the ratio between one resistor RB1 of the first current route portion and the resistor RB2 serving as the second resistance element 15. Thus, when the RAM circuit block RAM1 is selected, the voltage division ratio with respect to the RAM circuit block RAM1 becomes ((RB1+RB2)/RB2). Then, the internal power source control circuit 12 in the internal power source circuit 10 outputs the internal power source voltage VINT1 higher than the reference voltage VREF as the output voltage VINT1′, wherein VINT1′=VREF×((RB1+RB2)/RB2).

When the RAM circuit block is selected, the degree of the value of the voltage to be changed is determined based on the operation current of the selection RAM circuit block and the parasitic resistance of the internal power source wiring between the internal power source circuit and the power source port of the selection RAM circuit block.

When the RAM circuit block RAM1 is selected, the drop voltage is generated, correspondingly to (Iact×R1) obtained by multiplying the operation current Iact of the RAM circuit block RAM1 by the parasitic resistance R1 corresponding to the RAM circuit block RAM1 of the internal power source wiring. Consequently, as for the voltage applied to the power source port VINT11 of the RAM circuit block RAM1, the drop voltage corresponding to (Iact×R1) is dropped from the internal power source voltage VINT1 that is the output voltage of the internal power source circuit 10. Thus, when the RAM circuit block RAM1 is selected, the output voltage of the internal power source circuit 10 is changed to be high, correspondingly to this drop. That is, when the RAM circuit block RAM1 is selected, the value of the resistor RB1 is determined such that the voltage division ratio of the voltage dividing circuit 13 corresponds to a desirable voltage change value. In this case, the value of the resistor RB1 is determined such that the output voltage VINT1′ of the internal power source circuit 10 becomes the voltage in which the drop voltage corresponding to (Iact×RI) are added to the internal power source voltage VINT1, namely, (VINT1+(Iact×R1)).

Thus, when the RAM circuit block RAM1 is selected, the internal power source circuit 10 outputs (VINT1+(Iact×R1)) as its output voltage VINT1′. Hence, even if the drop is generated by the parasitic resistance of the internal power source wiring and the operation current of the RAM circuit block itself, the voltage VINT1 is applied to the power source port VINT11 of the RAM circuit block RAM1. In this way, even if there is the voltage drop caused by the parasitic resistance of the internal power source wiring, the LCD driver can be attained in which the access speed of the RAM circuit block RAM1 is not deteriorated.

The case when the RAM circuit block RAMn farthest from the internal power source circuit 10 is selected will be described below.

In order to select the RAM circuit block RAMn, the signal level of the RAM circuit block activation signal SELn is switched to the high level “H”. At this time, the RAM circuit block RAMn is made active. Also, by the NOR logic gate 21 inside the logic circuit 20, the signal level of the voltage division control signal CV0 is set to the low level “L”. Thus, in the first resistance element 14 of the voltage dividing circuit 13 in the internal power source circuit 10, the transmission gate G20 of the 0-th current route portion is turned off. Since the signal level of the RAM circuit block activation signal SELn is the high level “H”, the transmission gate G2n of the n-th current route portion is turned on. The transmission gates G21 to G2n−1 are in non-conduction state. At this time, the voltage dividing circuit 13 is switched to the voltage division ratio determined by the ratio between n number of resistors RB1 of the n-th current route portion and the resistor RB2 serving as the second resistance element 15. Thus, when the RAM circuit block RAMn is selected, the voltage division ratio with respect to the RAM circuit block RAMn becomes (((RB1×n)+RB2)/RB2). The internal power source control circuit 12 in the internal power source circuit 10 outputs VINT1′=VREF×(((RB1×n)+RB2)/RB2) as the output voltage VINT1′. In this case, the output voltage VINT1′ is the voltage higher than the output voltage VINT1′=VREF×((RB1+RB2)/RB2) when the RAM circuit block RAM1 is selected.

When the RAM circuit block RAMn is selected, the drop voltage is generated correspondingly to (Iact×(R1+R2+R3+ - - - +Rn−1+Rn) in which the operation current Iact of the RAM circuit block RAMn is multiplied by the parasitic resistance (R1+R2+R3+ - - - +Rn−1+Rn) corresponding to the RAM circuit block RAMn of the internal power source wiring. Thus, as for the voltage applied to the power source port VINT1n of the RAM circuit block RAMn, the drop voltage corresponding to (Iact×(R1+R2+R3+ - - - +Rn−1+Rn)) is dropped from the internal power source voltage VINT1 which is the output voltage of the internal power source circuit 10. Thus, when the RAM circuit block RAMn is selected, the output voltage of the internal power source circuit 10 is changed to be high, correspondingly to this drop. That is, when the RAM circuit block RAM1 is selected, the value of the resistors (RB1×n) may be determined such that the voltage division ratio of the voltage dividing circuit 13 corresponds to a desirable voltage change value. In this case, the value of the resistors (RB1×n) is be determined such that the output voltage VINT1′ of the internal power source circuit 10 becomes the voltage in which the drop voltage corresponding to (Iact×(R1+R2+R3+ - - - +Rn−1+Rn)) are added to the internal power source voltage VINT1 and, namely, VINT1+(Iact×(R1+R2+R3+ - - - +Rn−1+Rn)).

Thus, when the RAM circuit block RAMn is selected, the internal power source circuit 10 outputs VINT1+(Iact×(R1+R2+R3+ - - - +Rn−1+Rn)) as its output voltage VINT1′. Thus, even if the drop is generated by the parasitic resistance of the internal power source wiring and the operation current of the RAM circuit block itself, the voltage VINT1 is applied to the power source port VINT1n of the RAM circuit block RAMn. In this way, even if the RAM circuit block is arranged at the place away from the internal power source circuit 10, namely, even if the voltage drop caused by the parasitic resistance of the internal power source wiring is great, the LCD driver in which the access speed of the RAM circuit block RAMn is not deteriorated can be attained.

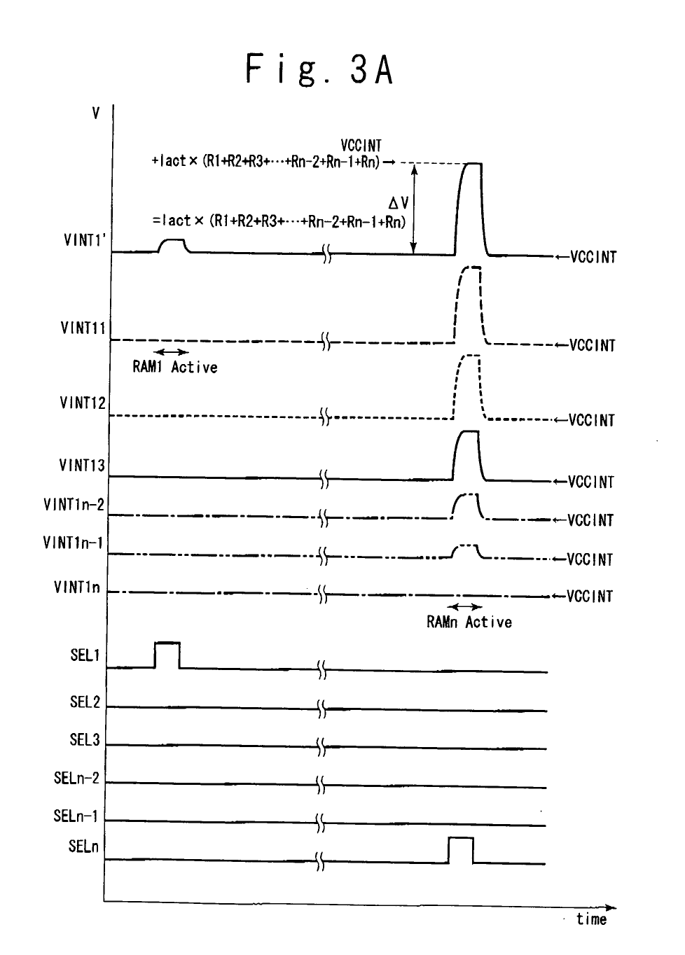

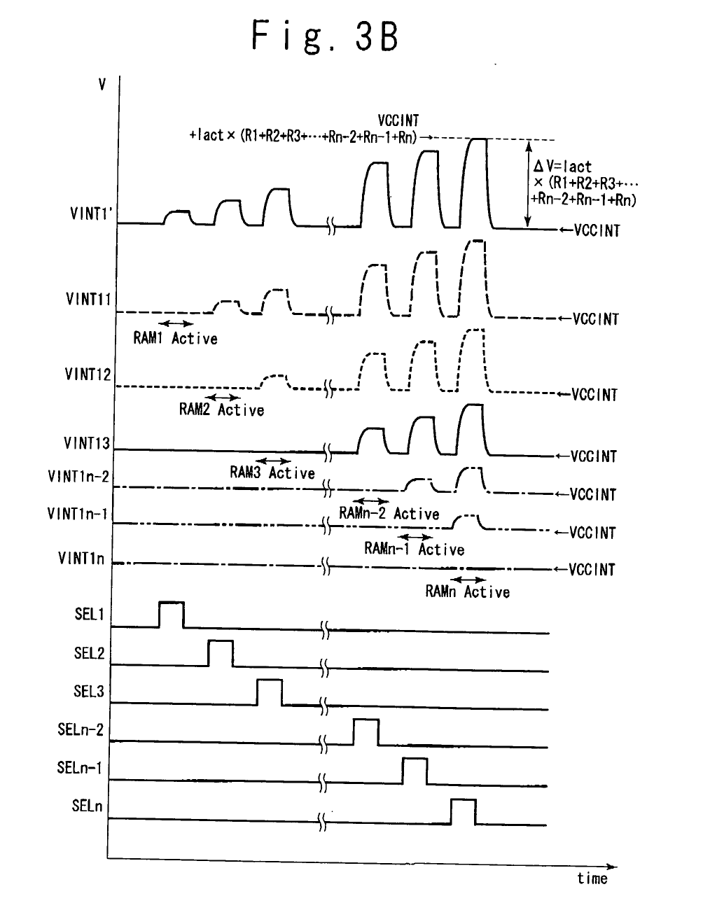

FIG. 3A is a timing chart showing a relation between the RAM circuit block activation signals SEL1 to SELn, the output voltage VINT1′ of the internal power source circuit 10 and the voltages applied to the power source ports VINT11 to VINT1n, as the operation of the semiconductor integrated circuit device according to the first embodiment of the present invention. Here, the horizontal axis indicates the time, the vertical axis indicates the voltage, and the “VCCINT” corresponds to the internal power source voltage VINT1. The output voltage VINT1′ of the internal power source circuit 10 is variably changed on the basis of the operation state of the RAM circuit blocks. When the RAM circuit block that is selected and operated is the RAM circuit block RAM1, the output voltage VINT1′ applied to the power source ports VINT11 to VINT1n is constantly controlled without being dropped.

The first embodiment has been described with regard to the RAM circuit block RAM1 arranged at the place closest to the internal power source circuit 10 and the RAM circuit block RAMn arranged at the place farthest from it. Similarly, as shown in FIG. 3B, the present invention can be also applied to the RAM circuit blocks RAM2 to RAMn−1 arranged in the middle between them, under the similar way of thinking.

### [Effect]

The effect of the semiconductor integrated circuit device according to the first embodiment of the present invention will be described below.

The semiconductor integrated circuit device according to the first embodiment of the present invention includes: the RAM circuit divided into the RAM circuit blocks RAM1 to RAMn; and the internal power source circuit 10. The selection RAM circuit block is selected from the RAM circuit blocks RAM1 to RAMn. At this time, the voltage drop arises in which the drop amount of the voltage (the drop voltage) is determined based on the parasitic resistance of the internal power source wiring between the internal power source circuit 10 and the selection RAM circuit block; and the operation current of the selection RAM circuit block. The parasitic resistance and the drop voltage are determined at the arrangement place of the selection RAM circuit block. Thus, the internal power source circuit 10 supplies the voltage based on the arrangement place of the selection RAM circuit block as the output voltage VINT1′, to the selection RAM circuit block. Consequently, according to the semiconductor integrated circuit device according to the first embodiment of the present invention, as its effect, the undesirable drop is not generated for the selection RAM circuit block currently in operation. Thus, the performance of the RAM circuit blocks RAM1 to RAMn is not deteriorated. That is, even if the optimal layout cannot be designed from the viewpoint of reducing the resistance of the internal power source wiring because the restriction on the chip shape is severe, the output voltage VINT1′ at which the access speed is not decreased can be supplied to the selection RAM memory circuit block away from the internal power source circuit 10. Also, according to the semiconductor integrated circuit device according to the first embodiment of the present invention, since the output level (output voltage VINT1′) of the internal power source circuit 10 is variably controlled only in the period when the selection RAM memory circuit block is operated, the increase in the operation current of the internal power source circuit 10 can be suppressed to the necessary minimum. Also, according to the semiconductor integrated circuit device according to the first embodiment of the present invention, the wiring width is not required to be made thick (wide) beyond necessity, for the sake of the lower resistance of the internal power source wiring than before. Hence, the increase in the chip size is avoided, and the cost reduction is attained.

According to the semiconductor integrated circuit device according to the first embodiment of the present invention, the RAM circuit blocks RAM1 to RAMn are arranged in the order, which starts with the RAM circuit block RAM1 closest to the internal power source circuit 10 and ends with the RAM circuit block RAMn farthest from the internal power source circuit 10. As mentioned above, for the RAM circuit blocks RAM1 to RAMn, the drop voltages are generated correspondingly to their arrangement places. Therefore, in order to attain the foregoing effect, in the internal power source circuit 10, n number of voltages corresponding to the parasitic resistances are set for each of the RAM circuit blocks RAM1 to RAMn. That is, the n number of the voltages are increased in the order, which starts with the voltage corresponding to the smallest parasitic resistance (R1) and ends with the voltage corresponding to the largest parasitic resistance (R1+ - - - +Rn). In this embodiment, the n number of the voltages are increased in the order, which starts with the voltage closest to the internal power source circuit 10 and ends with the voltage farthest from it. When the selection RAM circuit block is selected, the internal power source circuit 10 supplies the voltage based on the position of the selection RAM circuit block among the n number of the voltages, as the output voltage VINT1′, to the selection RAM circuit block. Thus, according to the semiconductor integrated circuit device according to the first embodiment of the present invention, the foregoing effect can be attained.

According to the semiconductor integrated circuit device according to the first embodiment of the present invention, in order to further attain the foregoing effect, the internal power source circuit 10 includes the voltage dividing circuit 13 that can generate the n number of the voltage division ratios (the first resistance element 14 (the (n+1) number of the current route portions) and the second resistance element 15) for setting the n number of the voltages. Here, the n number of the voltage division ratios (the first to n-th current route portions and the second resistance element 15) correspond to the RAM circuit blocks RAM1 to RAMn, respectively. When the selection RAM circuit block is selected, the internal power source circuit 10 selects the selection voltage division ratio corresponding to the selection RAM circuit block from the n number of the voltage division ratios, and supplies the voltage corresponding to the selection voltage division ratio among the n number of the voltages, as the output voltage VINT1′, to the selection RAM circuit block. Hence, according to the semiconductor integrated circuit device according to the first embodiment of the present invention, the foregoing effect can be attained.

According to the semiconductor integrated circuit device according to the first embodiment of the present invention, the RAM circuit block activation signals SEL1 to SELn are supplied to the RAM circuit blocks RAM1 to RAMn, respectively, when they are selected. Therefore, in order to further attain the foregoing effect, the logic circuit 20 outputs the voltage division control signal CVm for selecting the selection voltage division ratio corresponding to the selection RAM circuit block to the voltage dividing circuit 13, based on the RAM circuit block activation signal for selecting the selection RAM circuit block. At this time, the voltage dividing circuit 13 selects the selection voltage division ratio corresponding to the selection RAM circuit block, from the n number of the voltage division ratios, based on the voltage division control signal CVm. The internal power source circuit 10 supplies the voltage corresponding to the selection voltage division ratio among the n voltages, as the output voltage VINT1′, to the selection RAM circuit block. Thus, according to the semiconductor integrated circuit device according to the first embodiment of the present invention, the foregoing effect can be attained.

According to the semiconductor integrated circuit device according to the first embodiment of the present invention, the internal power source circuit 10 is connected to the internal power source wiring and generates the internal power source voltage VINT1. The RAM circuit blocks RAM1 to RAMn are connected to the internal power source wiring in parallel in the order, which starts with the RAM circuit block RAM1 closest to the internal power source circuit 10 and ends with the RAM circuit block RAMn farthest from the internal power source circuit 10. In the internal power source wiring, the parasitic resistances R1 to Rn are generated respectively corresponding to the arrangement places of the RAM circuit blocks RAM1 to RAMn. When the RAM circuit blocks RAM1 to RAMn are respectively selected and operated, the n number of the drop voltages, which are caused by the operation currents of the RAM circuit blocks RAM1 to RAMn and the parasitic resistances between the internal power source circuit 10 and the RAM circuit blocks RAM1 to RAMn, are generated in the RAM circuit blocks RAM1 to RAMn, respectively. Therefore, in order to further attain the foregoing effect, the n number of the voltages are the voltages in which the internal power source voltage VINT1 and the n number of the drop voltages are added, respectively.

Specifically, the resistance values of the parasitic resistances R1 to Rn, which correspond to the arrangement places of the RAM circuit blocks RAM1 to RAMn, respectively, are defined as R1 to Rn. The current value of the operation current of each of the RAM circuit blocks RAM1 to RAMn is defined as Iact. The voltage value of the internal power source voltage VINT1 is defined as VINT1. Also, the selection RAM circuit block is defined as the j-th RAM circuit block RAMj. Here, j is the integer, equal to or more than 1 and equal to or less than n. Also, among the n number of the voltages, the voltage for the j-th RAM circuit block RAMj is defined as the output voltage VINT1′. In this case, the output voltage VINT1′ is represented by the following equation [1].

$$VINT {1}^{′} = VINT 1 + ( Iact \times {\sum }_{t = 1}^{j} Ri ) \qquad [ Equation 1 ]$$

Consequently, according to the semiconductor integrated circuit device according to the first embodiment of the present invention, the foregoing effect can be obtained.

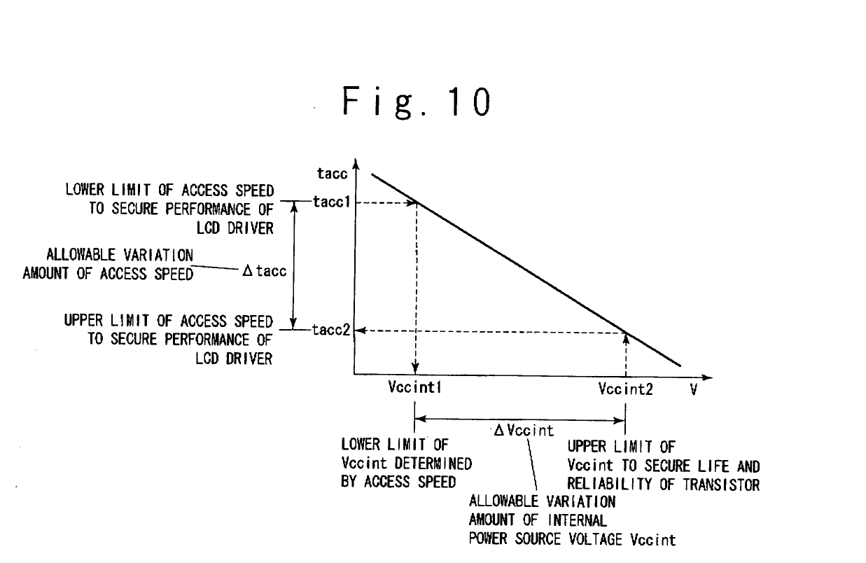

Incidentally, in the semiconductor integrated circuit device according to the first embodiment of the present invention, the mechanism is described in which as for the n number of the RAM circuit blocks provided in the LCD driver, the output voltage VINT1′ of the internal power source circuit 10 is controlled at n number of steps on the basis of the selection RAM circuit block. However, it is not limited to this case. As the variation example of the semiconductor integrated circuit device according to the first embodiment of the present invention, the number of the control steps may be reduced within the range of the allowable internal power source voltage and access speed (this fact will be described in FIG. 10).

Here, a variation example of the semiconductor integrated circuit device according to the first embodiment of the present invention is described.

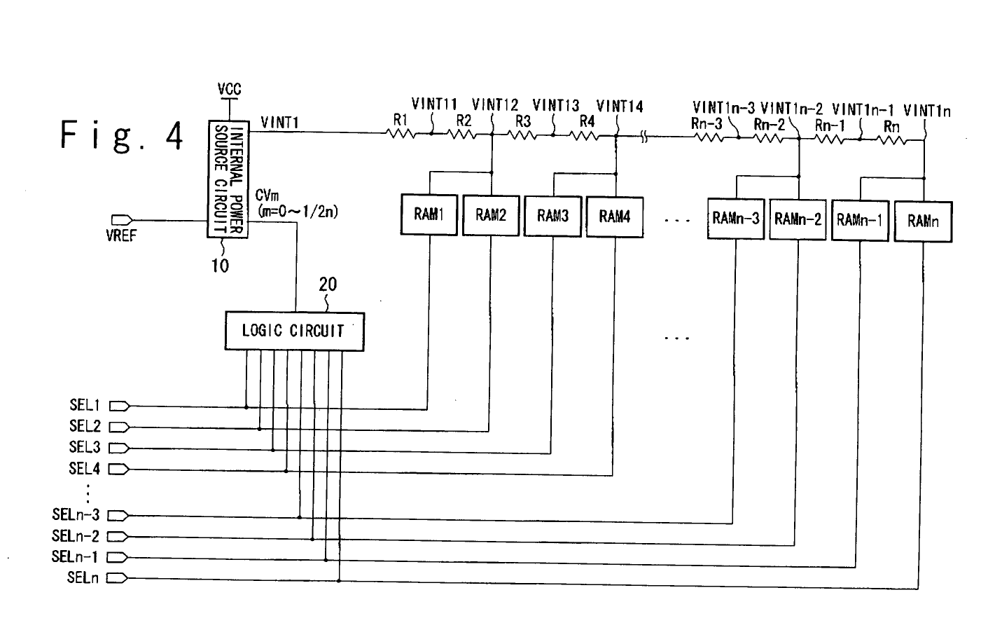

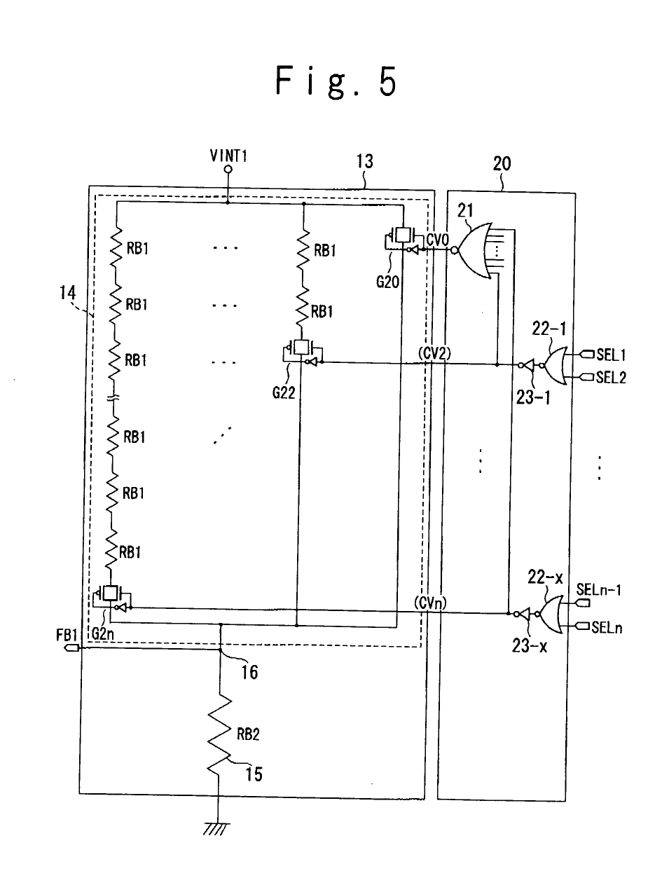

FIG. 4 is a view showing a configuration of a variation example 1 of the semiconductor integrated circuit device according to the first embodiment of the present invention. FIG. 5 is a view showing a configuration of an example of the voltage dividing circuit 13 and the logic circuit 20 in the variation example 1.

In the variation example 1 of the semiconductor integrated circuit device according to the first embodiment of the present invention, it is assumed that the first to n-th (n is the integer) RAM circuit blocks RAM1 to RAMn constitute x (x is the integer smaller than n) number of RAM circuit block groups, and N number of the RAM circuit blocks belong to each of the x number of the RAM circuit block groups. Here, the N is the integer satisfying n=x×N. Therefore, when N=2 is defined, the x number of the RAM circuit block groups are represented as the RAM circuit blocks RAM1 to RAM2, RAM3 to RAM4, - - - , and RAMn−1 to RAMn, respectively. These RAM circuit blocks RAM1 to RAM2, - - - , and RAMn−1 to RAMn are arranged in the order, which starts with the RAM circuit blocks RAM1 closest to the internal power source circuit 10 and ends with the RAM circuit blocks RAMn farthest from the internal power source circuit 10. In this case, in the internal power source wiring connected to the internal power source circuit 10, the parasitic resistances R1 to R2, - - - , and Rn−1 to Rn are generated, respectively corresponding to the arrangement places of the RAM circuit blocks RAM1 to RAM2, - - - , and RAMn−1 to RAMn. Thus, for the RAM circuit blocks RAM1 to RAM2, - - - , and RAMn−1 to RAMn, the drop voltages are generated, correspondingly to their arrangement places. Therefore, in order to attain the foregoing effect, in the internal power source circuit 10, x number of voltages corresponding to the parasitic resistances are set for each of the RAM circuit blocks RAM1 to RAM2, - - - , and RAMn−1 to RAMn (each of the RAM circuit block groups). That is, the x number of the voltages are increased in the order, which starts with the voltage corresponding to the smallest parasitic resistance (R1+R2) and ends with the voltage corresponding to the greatest parasitic resistance (R1+ - - - +Rn). In this embodiment, the x number of the voltages are increased in the order, which starts with the voltage closest to the internal power source circuit 10 and ends with the voltage farthest from the internal power source circuit 10. When the selection RAM circuit block is selected, the internal power source circuit 10 supplies the voltage corresponding to a position of the selection RAM circuit block among the x number of the voltages, as the output voltage VINT1′ to the selection RAM circuit block. Hence, according to the variation example 1 of the semiconductor integrated circuit device according to the first embodiment of the present invention, the number of the control steps can be reduced from the n to x (x=(½)×n).

In the variation example 1 of the semiconductor integrated circuit device according to the first embodiment of the present invention, in order to further attain the foregoing effect, the internal power source circuit 10 includes the voltage dividing circuit 13 that can generate x number of voltage division ratios (the first resistance element 14 ((x+1) number of current route portions) and the second resistance element 15) to set the x number of the voltages. Here, the x number of the voltage division ratios (the first to x-th current route portions and the second resistance element 15) correspond to the RAM circuit blocks RAM1 to RAM2, - - - , and RAMn−1 to RAMn, respectively. When the selection RAM circuit block is selected, the internal power source circuit 10 selects the selection voltage division ratio corresponding to the selection RAM circuit block, from the x number of the voltage division ratios, and supplies the voltage corresponding to the selection voltage division ratio among the x number of the voltages, as the output voltage VINT1′ to the selection RAM circuit block. Thus, according to the variation example 1 of the semiconductor integrated circuit device according to the first embodiment of the present invention, the foregoing effect can be attained.

In the variation example 1 of the semiconductor integrated circuit device according to the first embodiment of the present invention, the RAM circuit block activation signals SEL1 to SEL2, - - - , and SELn−1 to SELn are supplied to the RAM circuit blocks RAM1 to RAM2, - - - , and RAMn−1 to RAMn, respectively, when they are selected. Specifically, as shown in FIG. 5, the logic circuit 20 further includes: NOR logic gates 22-1 to 22-x; and inverters (inversion gates) 23-1 to 23-x. The NOR logic gates 22-1 to 22-x receive the RAM circuit block activation signals SEL1 to SEL2, - - - , and SELn−1 to SELn, respectively. Then, the NOR logic gates 22-1 to 22-x carry out NOR (negative OR) operations based on the signal levels of the RAM circuit block activation signals SEL1 to SEL2, - - - , and SELn−1 to SELn, respectively. After that, the NOR logic gates 22-1 to 22-x output their results to the inverters 23-1 to 23-x, respectively. The inverters 23-1 to 23-x invert the foregoing results and output them to the NOR logic gate 21. The inverters 23-1 to 23-x also output their inversion results as the voltage division control signals CV2 to CVn, respectively, to the voltage dividing circuit 13. The NOR logic gate 21 receives the voltage division control signals CV2 to CVn, carries out the NOR operation based on the signal levels of the voltage division control signals CV2 to CVn and then outputs the voltage division control signal CV0 as its result to the voltage dividing circuit 13. The first resistance element 14 in the voltage dividing circuit 13 includes the (x+1) number of the current route portions that are connected in parallel to set the x number of the voltages. Therefore, in order to further attain the foregoing effect, the logic circuit 20 outputs the voltage division control signal CVm for selecting the selection voltage division ratio corresponding to the selection RAM circuit block to the voltage dividing circuit 13, on the basis of the RAM circuit block activation signal for selecting the selection RAM circuit block. At this time, the voltage dividing circuit 13 selects the selection voltage division ratio corresponding to the selection RAM circuit block, from the x number of the voltage division ratios, on the basis of the voltage division control signal CVm. The internal power source circuit 10 supplies the voltage corresponding to the selection voltage division ratio among the x number of the voltages, as the output voltage VINT1′, to the selection RAM circuit block. Hence, according to the variation example 1 of the semiconductor integrated circuit device according to the first embodiment of the present invention, the foregoing effect can be attained.

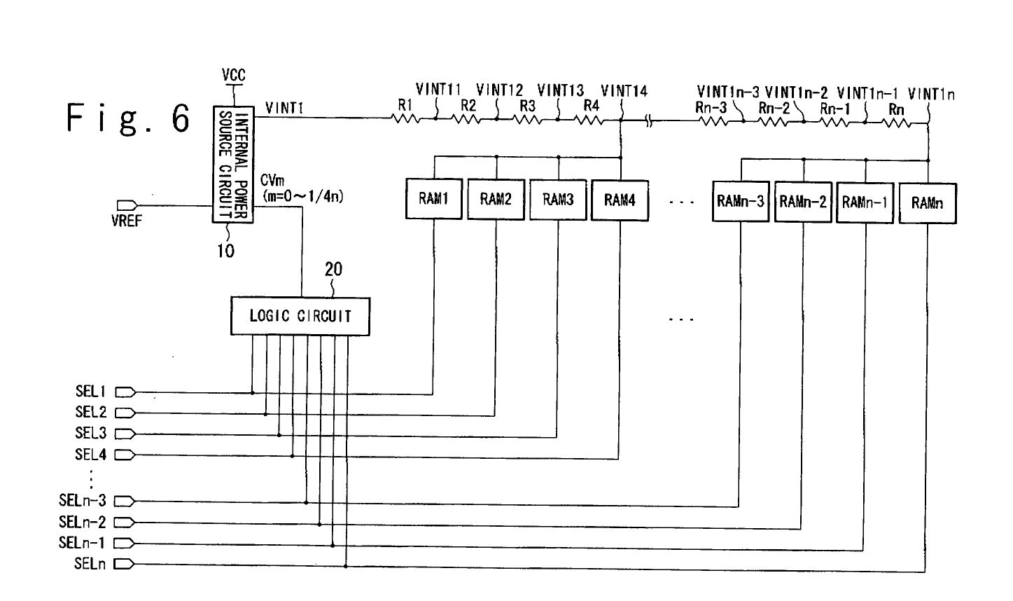

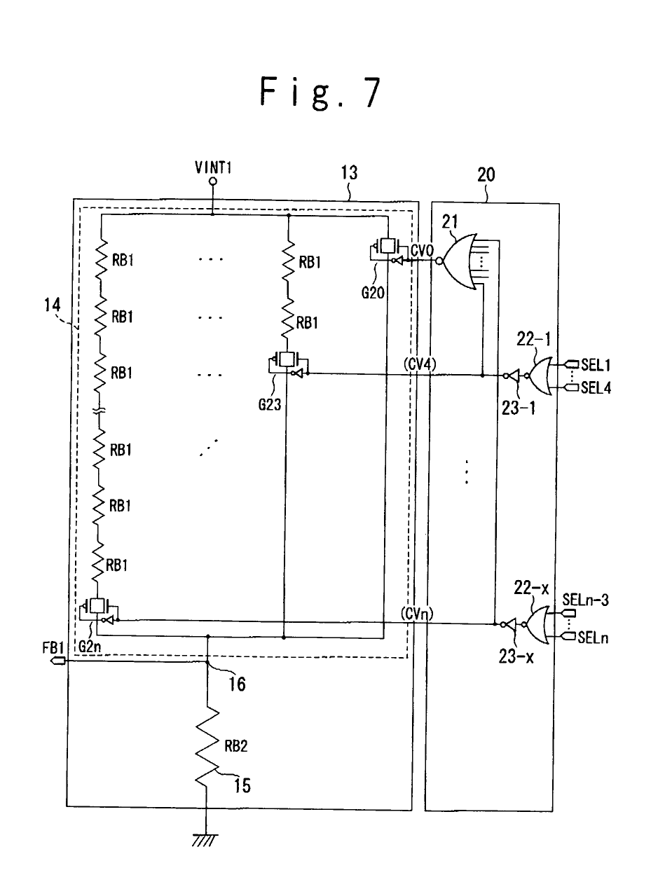

FIG. 6 is a view showing a configuration of a variation example 2 of the semiconductor integrated circuit device according to the first embodiment of the present invention. FIG. 7 is a view showing a configuration of an example of the voltage dividing circuit 13 and the logic circuit 20 in the variation example 2.

In the variation example 2 of the semiconductor integrated circuit device according to the first embodiment of the present invention, it is assumed that the first to n-th (n is the integer) RAM circuit blocks RAM1 to RAMn constitute x (x is the integer smaller than n) number of RAM circuit block groups, and N number of the RAM circuit blocks belong to each of the x number of the RAM circuit block groups. Here, the N is the integer satisfying n=x×N. Therefore, when N=4 is defined, the x number of the RAM circuit block groups are represented as the RAM circuit block groups RAM1 to RAM4, RAM5 to RAM 8, - - - , and RAMn−3 to RAMn, respectively. The RAM circuit blocks RAM1 to RAM4, - - - , and RAMn−3 to RAMn are arranged in the order, which starts with the RAM circuit block RAM1 closest to the internal power source circuit 10 and ends with the RAM circuit block RAMn farthest from the internal power source circuit 10. In this case, in the internal power source wiring connected to the internal power source circuit 10, the parasitic resistances R1 to R4, - - - , and Rn−3 to Rn are generated, respectively corresponding to the arrangement places of the RAM circuit blocks RAM1 to RAM4, - - - , and RAMn−3 to RAMn. Thus, for the RAM circuit blocks RAM1 to RAM4, - - - , and RAMn−3 to RAMn, the drop voltages are generated, correspondingly to their arrangement places. Therefore, in order to attain the foregoing effect, in the internal power source circuit 10, x number of voltages corresponding to the parasitic resistances are set for each of the RAM circuit blocks RAM1 to RAM4, - - - , and RAMn−3 to RAMn (each of the RAM circuit block groups). That is, the x number of the voltages are increased in the order, which starts with the voltage corresponding to the smallest parasitic resistance (R1+R2+R3+R4) and ends with the voltage corresponding to the greatest parasitic resistance (R1+ - - - +Rn). In this embodiment, the x number of the voltages are increased in the order, which starts with the voltage closest to the internal power source circuit 10 and the voltage farthest from the internal power source circuit 10. When the selection RAM circuit block is selected, the internal power source circuit 10 supplies the voltage corresponding to a position of the selection RAM circuit block among the x number of the voltages, as the output voltage VINT1′, to the selection RAM circuit block. Hence, according to the variation example 2 of the semiconductor integrated circuit device according to the first embodiment of the present invention, the number of the control steps can be reduced from the n to x (x=(¼)×n).

In the variation example 2 of the semiconductor integrated circuit device according to the first embodiment of the present invention, in order to further attain the foregoing effect, the internal power source circuit 10 includes the voltage dividing circuit 13 that can generate x number of voltage division ratios (the first resistance element 14 ((x+1) number of current route portions) and the second resistance element 15) to set the x number of the voltages. Here, the x number of the voltage division ratios (the first to x-th current route portions and the second resistance element 15) correspond to the RAM circuit blocks RAM1 to RAM4, - - - , and RAMn−3 to RAMn, respectively. When the selection RAM circuit block is selected, the internal power source circuit 10 selects the selection voltage division ratio corresponding to the selection RAM circuit block, from the x number of the voltage division ratios, and supplies the voltage corresponding to the selection voltage division ratio among the x number of the voltages, as the output voltage VINT1′, to the selection RAM circuit block. Hence, according to the variation example 2 of the semiconductor integrated circuit device according to the first embodiment of the present invention, the foregoing effect can be attained.

In the variation example 2 of the semiconductor integrated circuit device according to the first embodiment of the present invention, the RAM circuit block activation signals SEL1 to SEL4, - - - , and SELn−3 to SELn are supplied to the RAM circuit blocks RAM1 to RAM4, - - - , and RAMn−3 to RAMn, respectively, when they are selected. Specifically, as shown in FIG. 7, the logic circuit 20 further includes: the NOR logic gates 22-1 to 22-x; and the inverters (inversion gates) 23-1 to 23-x. The NOR logic gates 22-1 to 22-x receives the RAM circuit block activation signals SEL1 to SEL4, - - - , and SELn−3 to SELn, respectively. Then, the NOR logic gates 22-1 to 22-x carry out the NOR operations based on the signal levels of the RAM circuit block activation signals SEL1 to SEL4, - - - , and SELn−3 to SELn, respectively. After that, the NOR logic gates 22-1 to 22-x output their results to the inverters 23-1 to 23-x, respectively. The inverters 23-1 to 23-x invert the foregoing results and output to the NOR logic gate 21. The inverters 23-1 to 23-x also output their inversion results as the voltage division control signals CV4 to CVn, respectively, to the voltage dividing circuit 13. The NOR logic gate 21 receives the voltage division control signals CV4 to CVn, carries out the NOR operation based on the signal levels of the voltage division control signals CV4 to CVn and then outputs the voltage division control signal CV0 as its result to the voltage dividing circuit 13. The first resistance element 14 in the voltage dividing circuit 13 includes the (x+1) number of the current route portions that are connected in parallel to set the x number of the voltages. Therefore, in order to further attain the foregoing effect, the logic circuit 20 outputs the voltage division control signal CVm for selecting the selection voltage division ratio corresponding to the selection RAM circuit block to the voltage dividing circuit 13, on the basis of the RAM circuit block activation signal for selecting the selection RAM circuit block. At this time, the voltage dividing circuit 13 selects the selection voltage division ratio corresponding to the selection RAM circuit block, from the x number of the voltage division ratios, on the basis of the voltage division control signal CVm. The internal power source circuit 10 supplies the voltage corresponding to the selection voltage division ratio among the x number of the voltages, as the output voltage VINT1′, to the selection RAM circuit block. Hence, according to the variation example 2 of the semiconductor integrated circuit device according to the first embodiment of the present invention, the foregoing effect can be attained.

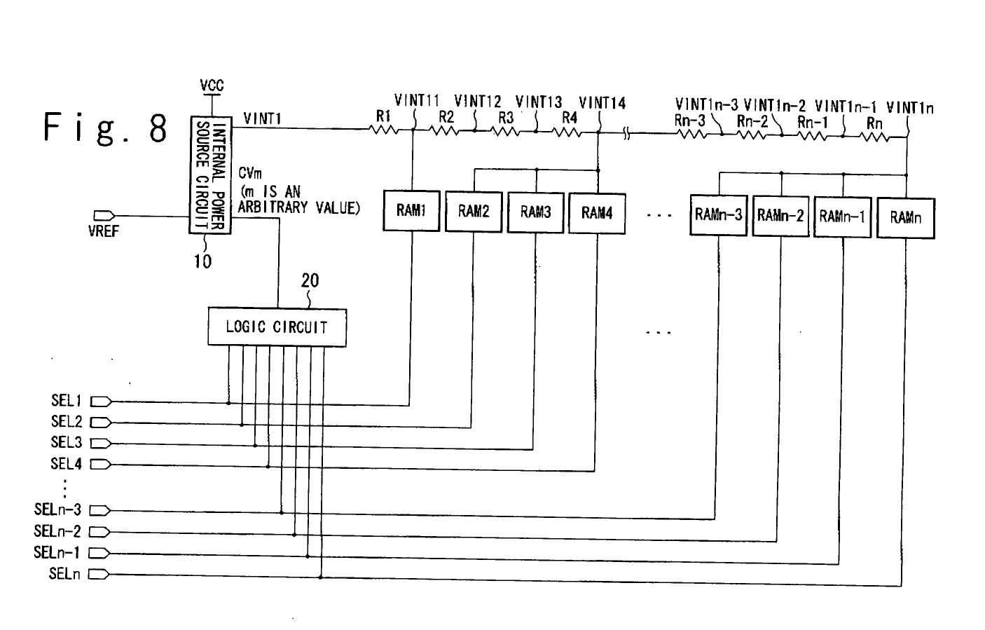

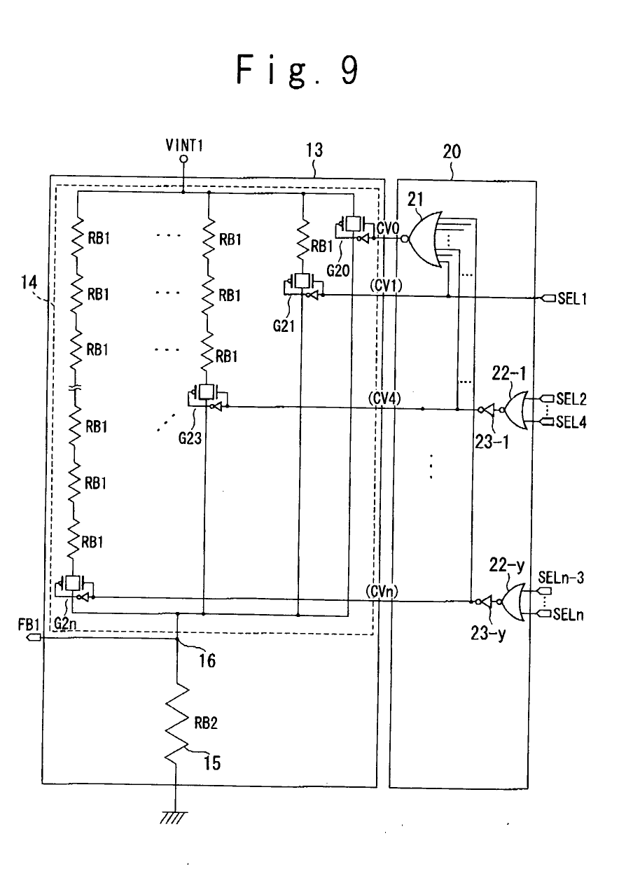

FIG. 8 is a view showing a configuration of a variation example 3 of the semiconductor integrated circuit device according to the first embodiment of the present invention. FIG. 9 is a view showing a configuration of an example of the voltage dividing circuit 13 and the logic circuit 20 in the variation example 3.

In the variation example 3 of the semiconductor integrated circuit device according to the first embodiment of the present invention, it is assumed that the first to n-th (n is the integer) RAM circuit blocks RAM1 to RAMn constitute x (x is the integer smaller than the n) number of RAM circuit block groups, and the number of the RAM circuit blocks belonging to each of the x number of the RAM circuit block groups are different from each other. For example, the x number of the RAM circuit block groups are represented as the RAM circuit block groups RAM1, RAM2 to RAM4, - - - , and RAMn−3 to RAMn, respectively. The RAM circuit blocks RAM1, RAM2 to RAM4, - - - , and RAMn−3 to RAMn are arranged in the order, which starts with the RAM circuit block RAM1 closest to the internal power source circuit 10 and ends with the RAM circuit block RAMn farthest from the internal power source circuit 10. In this case, in the internal power source wiring connected to the internal power source circuit 10, the parasitic resistances R1, R2 to R4, - - - , and Rn−3 to Rn are generated, respectively correspondingly to the arrangement places of the RAM circuit blocks RAM1, RAM2 to RAM4, - - - , and RAMn−3 to RAMn. Thus, for the RAM circuit blocks RAM1, RAM2 to RAM4, - - - , and RAMn−3 to RAMn, the drop voltages are generated, correspondingly to their arrangement places. Therefore, in order to attain the foregoing effect, in the internal power source circuit 10, x number voltages corresponding to the parasitic resistances are set for each of the RAM circuit blocks RAM1, RAM2 to RAM4, - - - , and RAMn−3 to RAMn (each of the RAM circuit block groups). That is, the x number of the voltages are increased in the order, which starts with the voltage corresponding to the smallest parasitic resistance (R1) and ends with the voltage corresponding to the greatest parasitic resistance (R1+ - - - +Rn). In this embodiment, the x number of the voltages are increased in the order, which starts with the voltage closest to the internal power source circuit 10 and ends with the voltage farthest from the internal power source circuit 10. When the selection RAM circuit block is selected, the internal power source circuit 10 supplies the voltage corresponding to a position of the selection RAM circuit block among the x number of the voltages, as the output voltage VINT1′, to the selection RAM circuit block. Hence, according to the variation example 3 of the semiconductor integrated circuit device according to the first embodiment of the present invention, the number of the control steps can be reduced from the n to the x.

In the variation example 3 of the semiconductor integrated circuit device according to the first embodiment of the present invention, in order to further attain the foregoing effect, the internal power source circuit 10 includes the voltage dividing circuit 13 that can generate x number of voltage division ratios (the first resistance element 14 ((x+1) number of current route portions) and the second resistance element 15) to set the x number of the voltages. Here, the x number of the voltage division ratios (the first to x-th current route portions and the second resistance element 15) correspond to the RAM circuit blocks RAM1, RAM2 to RAM4, - - - , and RAMn−3 to RAMn, respectively. When the selection RAM circuit block is selected, the internal power source circuit 10 selects the selection voltage division ratio corresponding to the selection RAM circuit block, from the x number of the voltage division ratios, and supplies the voltage corresponding to the selection voltage division ratio among the x number of the voltages, as the output voltage VINT1′ to the selection RAM circuit block. Hence, according to the variation example 3 of the semiconductor integrated circuit device according to the first embodiment of the present invention, the foregoing effect can be attained.

In the variation example 3 of the semiconductor integrated circuit device according to the first embodiment of the present invention, the RAM circuit block activation signals SEL1, SEL2 to SEL4, - - - , and SELn−3 to SELn are supplied to the RAM circuit blocks RAM1, RAM2 to RAM4, - - - , and RAMn−3 to RAMn, respectively, when they are selected. Specifically, as shown in FIG. 9, the logic circuit 20 further includes the NOR logic gates 22-1 to 22-y (in this case, y is an integer satisfying y=x+1) and the inverters (inversion gates) 23-1 to 23-y. In this case, the logic circuit 20 outputs the RAM circuit block activation signal SEL1 as the voltage division control signal CV1 to the NOR logic gate 21 and the voltage dividing circuit 13. The NOR logic gates 22-1 to 22-y receives the RAM circuit block activation signals SEL2 to SEL4, - - - , and SELn−3 to SELn, respectively. Then, the NOR logic gates 22-1 to 22-y carry out the NOR operations based on the signal levels of the RAM circuit block activation signals SEL2 to SEL4, - - - , and SELn−3 to SELn, respectively. After that, the NOR logic gates 22-1 to 22-y output their results to the inverters 23-1 to 23-y, respectively. The inverters 23-1 to 23-y invert the foregoing results and output to the NOR logic gate 21. The inverters 23-1 to 23-y also output their inversion results as the voltage division control signals CV4 to CVn, respectively, to the voltage dividing circuit 13. The NOR logic gate 21 receives the voltage division control signals CV1, CV4 to CVn, carries out the NOR operation based on the signal levels of the voltage division control signals CV1, CV4 to CVn and then outputs the voltage division control signal CV0 as its result to the voltage dividing circuit 13. The first resistance element 14 in the voltage dividing circuit 13 includes (x+1) number of current route portions that are connected in parallel to set x number of voltages. Therefore, in order to further attain the foregoing effect, the logic circuit 20 outputs the voltage division control signal CVm for selecting the selection voltage division ratio corresponding to the selection RAM circuit block to the voltage dividing circuit 13, on the basis of the RAM circuit block activation signal for selecting the selection RAM circuit block. At this time, the voltage dividing circuit 13 selects the selection voltage division ratio corresponding to the selection RAM circuit block, from the x number of the voltage division ratios, on the basis of the voltage division control signal CVm. The internal power source circuit 10 supplies the voltage based on the selection voltage division ratio among the x number of the voltages, as the output voltage VINT1′, to the selection RAM circuit block. Hence, according to the variation example 3 of the semiconductor integrated circuit device according to the first embodiment of the present invention, the foregoing effect can be attained.

In the variation example 3 of the semiconductor integrated circuit device according to the first embodiment of the present invention, the RAM circuit blocks RAM1, RAM2 to RAM4, - - - , and RAMn−3 to RAMn are arranged in the order as the RAM circuit block groups that have the one, three, - - - , and four RAM circuit blocks, respectively. However, they are not limited to this case. Those orders may be changed, depending on the value of the parasitic resistance.

### Second Embodiment

The first embodiment is described with regard to the case in which the number of the RAM circuit blocks currently in operation is one. However, the semiconductor integrated circuit device according to the second embodiment of the present invention is described with regard to the case in which a plurality of RAM circuit blocks currently in operation exist at the same time. In the second embodiment, the explanations overlapping with the first embodiment are omitted.

### [Configuration]

The configuration of the semiconductor integrated circuit device according to the second embodiment of the present invention is similar to that of the first embodiment.

### [Operation]

As an operation of the semiconductor integrated circuit device according to the second embodiment of the present invention, in order to simplify the description, a case is described in which two RAM circuit blocks currently in operation exist. Here, an operation current of one RAM circuit block is defined as Iact.

In order to select the RAM circuit blocks RAM1, RAM2, the signal levels of the RAM circuit block activation signals SEL1, SEL2 are switched to the high level “H”. At this time, the RAM circuit blocks RAM1, RAM2 are made active.

The internal power source circuit 10 compares the divided voltage FB1 and the reference voltage VREF and adjusts the internal power source voltage VINT1. As for the divided voltage FB1, its voltage division ratio is controlled by the voltage division control signals CV0 to CVm outputted from the logic circuit 20. As described in the first embodiment, in the period when the RAM circuit block is selected and operated, the internal power source circuit 10 sets the internal power source voltage VINT1 to be high, on the basis of the drop amount of the internal power source voltage when the RAM circuit block is operated. Therefore, when the plurality of RAM circuit blocks are operated, an increase amount of the voltage change is required to be determined based on balance between performance of the RAM circuit blocks and entire performance of the LCD driver. The principle will be described below.

FIG. 10 is a graph showing a relation between an access speed of the RAM circuit block and a power source voltage applied to the RAM circuit block. The horizontal axis indicates the power source voltage Vccint, and the vertical axis indicates the access speed tacc. The downward-sloping line (from top left to bottom right) indicates the negative internal power source voltage dependence of the access speed of the RAM circuit block. A symbol Vccint1 indicates the lower limit of the internal power source voltage determined based on the access speed. A symbol Vccint2 indicates the upper limit of the internal power source voltage allowable to be applied to the RAM circuit block in order to secure the lives and reliabilities of the transistors configuring the circuit. A symbol ΔVccint indicates the allowable variation amount of the internal power source voltage Vccint. That is, the ΔVccint indicates the upper limit of the range of the internal power source voltage Vccint. A symbol tacc1 indicates the lower limit of the access speed of the RAM circuit block in order to secure the performance of the LCD driver. A symbol tacc2 indicates the upper limit of the access speed of the RAM circuit block in order to secure the performance of the LCD driver. A symbol ΔVtacc indicates the allowable variation amount of the access speed tacc of the RAM circuit block, which is allowable for the logic circuit which outputs and receives the data to and from the RAM circuit block. That is, the ΔVtacc indicates the upper limit of the range of the access speed tacc of the RAM circuit block.

In the RAM circuit block, there is the allowable internal power source voltage variation ΔVccint that is determined based on the allowable access speed variation ΔVtacc. When the plurality of RAM circuit blocks are operated at the same time, the drop compensation amount of the internal power source voltage (drop voltage) may be determined such that it falls in the ranges of the allowable internal power source voltage and the allowable access speed.

Typically, in the lower internal power source voltage, the RAM circuit block has a smaller margin with regard to the circuit performance, in many cases. Therefore, in this embodiment, as an example, the performance of the RAM circuit block RAM2 arranged at the place away from the internal power source circuit 10 is compensated. That is, the drop in the internal power source voltage applied to the power source port of the RAM circuit block RAM2 is compensated.

In such an example, on the basis of the operation currents Iact×2 of the selected RAM circuit blocks RAM1, RAM2 and the parasitic resistances (R1+R2) of the internal power source wiring between the internal power source circuit 10 and the power source port of the RAM circuit block RAM2, the drop compensation amount of the internal power source voltage becomes (((Iact×2)×R1)+(Iact×R2)). In this case, the internal power source voltage applied to the power source port VINT11 of the RAM circuit block RAM1 becomes (VINT1+(Iact×R2)). Thus, correspondingly to (Iact×R2), the internal power source voltage applied to the RAM circuit block RAM1 is high. Of course, as described above, if the internal power source voltage falls in the range of the allowable internal power source voltage and the allowable access speed, there is no problem on the circuit operation. If the internal power source voltage does not fall in the range, ideas such as decrease in the operation current of the RAM circuit block and decrease in the parasitic resistance of the internal power source wiring and the like are required (this case will be described later in the third embodiment).

Thus, when the RAM circuit blocks RAM1, RAM2 are selected, the internal power source circuit 10 outputs the voltage in which the drop voltage corresponding to (Iact×2)×R1)+(Iact×R2)) are added to the internal power source voltage VINT1, namely, VINT1+(((Iact×2)×R1)+(Iact×R2)) as the output voltage VINT1′. Thus, even if the drop voltage is generated based on the parasitic resistance of the internal power source wiring and the operation currents of the RAM circuit blocks RAM1, RAM2, the voltage of VINT1 is applied to a power source port VINT12 of the RAM circuit block RAM2 away from the internal power source 13. In this way, even if there is the drop of the voltage caused by the parasitic resistance of the internal power source wiring, the LCD driver can be attained in which the access speed of the RAM circuit block RAM2 is not deteriorated.

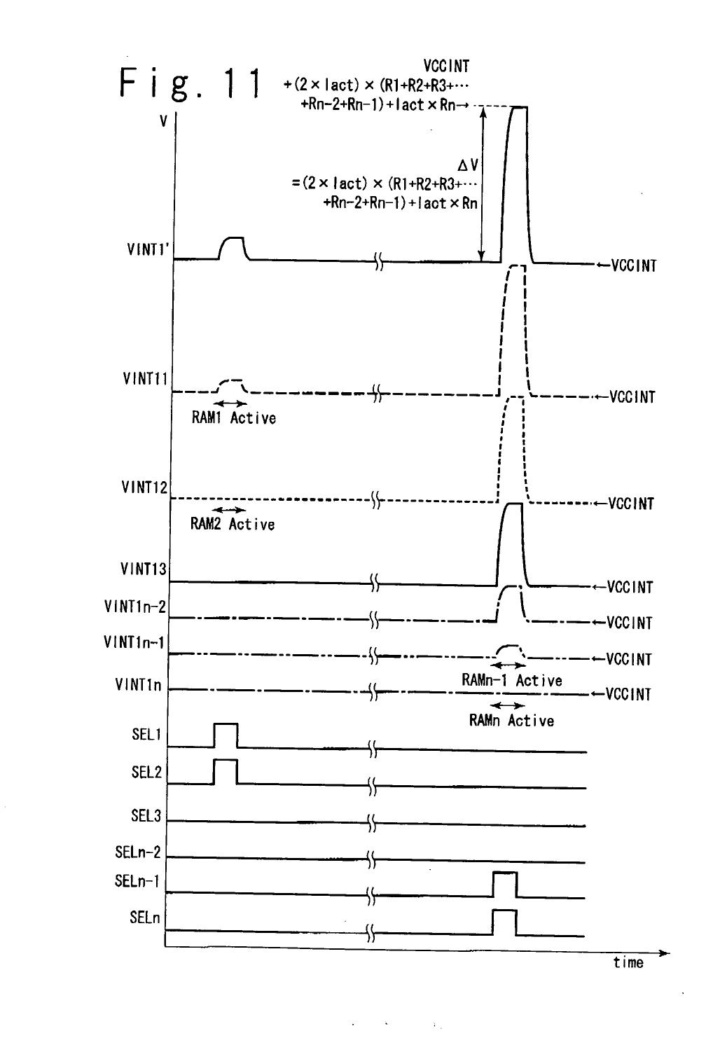

FIG. 11 is a timing chart showing a relation between the RAM circuit block activation signals SEL1 to SELn, the output voltage VINT1′ of the internal power source circuit 10 and the voltages applied to the power source ports VINT11 to VINT1n, as the operation of the semiconductor integrated circuit device according to the second embodiment of the present invention. Here, the horizontal axis indicates the time, and the vertical axis indicates the voltage. The output voltage VINT1′ of the internal power source circuit 10 is variably controlled based on the operation state of the RAM circuit block. When the RAM circuit blocks that are selected and operated are the RAM circuit blocks RAM1, RAM2, the output voltage VINT1′ applied to the internal power source ports VINT12 to VINT1n are constantly controlled without being dropped.

The second embodiment has been described with regard to the RAM circuit blocks RAM1, RAM2 and the RAM circuit blocks RAMn−1, RAMn. However, the present invention can be applied even to the case in which there are a plurality of accesses to be operated at the same time, under the similar way of thinking.

Also, from the viewpoint of decreasing the setting range of the internal power source voltage, when the plurality of RAM circuit blocks are activated at the same time, the RAM circuit blocks that are operated at the same time are desired to be adjacently arranged because the difference of the parasitic resistance between the internal power source wirings can be small in the adjacent RAM circuit blocks. Conversely, the adjacent RAM circuit blocks are desired to be selectively controlled to be operated at the same time. However, as shown also in FIG. 10, if the drop voltage of the internal power source voltage matches with and falls in the allowable variation ranges of the internal power source voltage and the access speed, the control process is not limited to the control that always selects the adjacent RAM circuit blocks at the same time. Thus, when there is another design subject with the higher priority, the arrangement of the RAM circuit block and the selecting operation may be optimized based on the priority.

As mentioned above, as the second embodiment, the case in which the two RAM circuit blocks are operated at the same time is described. However, of course, the present invention can be applied to a case in which the three or more RAM circuit blocks are operated at the same time, within the range of the foregoing limit.

### [Effect]

The effect of the semiconductor integrated circuit device according to the second embodiment of the present invention will be described below.

According to the second embodiment of the present invention, the semiconductor integrated circuit device includes: the RAM circuit divided into the RAM circuit blocks RAM1 to RAMn; and the internal power source circuit 10. The selection RAM circuit block including the two or more RAM circuit blocks is selected from the RAM circuit blocks RAM1 to RAMn. At this time, the internal power source circuit 10 supplies the voltage based on the arrangement place of the selection RAM circuit block, as the output voltage VINT1′, to the selection RAM circuit block. Thus, the semiconductor integrated circuit device according to the second embodiment of the present invention attains the effect similar to that of the first embodiment.

Also, according to the second embodiment of the present invention, the semiconductor integrated circuit device can be applied to the case in which the plurality of RAM circuit blocks are operated at the same time, in addition to the effect of the first embodiment. According to the semiconductor integrated circuit device according to the second embodiment of the present invention, the plurality of RAM circuit blocks are operated at the same time. Thus, the data access speed can be made higher, thereby enabling the higher performance of the LCD driver.

### Third Embodiment

As the idea for falling in the ranges of the allowable internal power source voltage and the allowable access speed that is explained in the second embodiment, the semiconductor integrated circuit device according to the third embodiment of the present invention is described with regard to a method of decreasing an operation current of the RAM circuit block and decreasing the parasitic resistance of the internal power source wiring. In the third embodiment, the descriptions overlapping with those of the first and second embodiments are omitted.

### [Configuration]

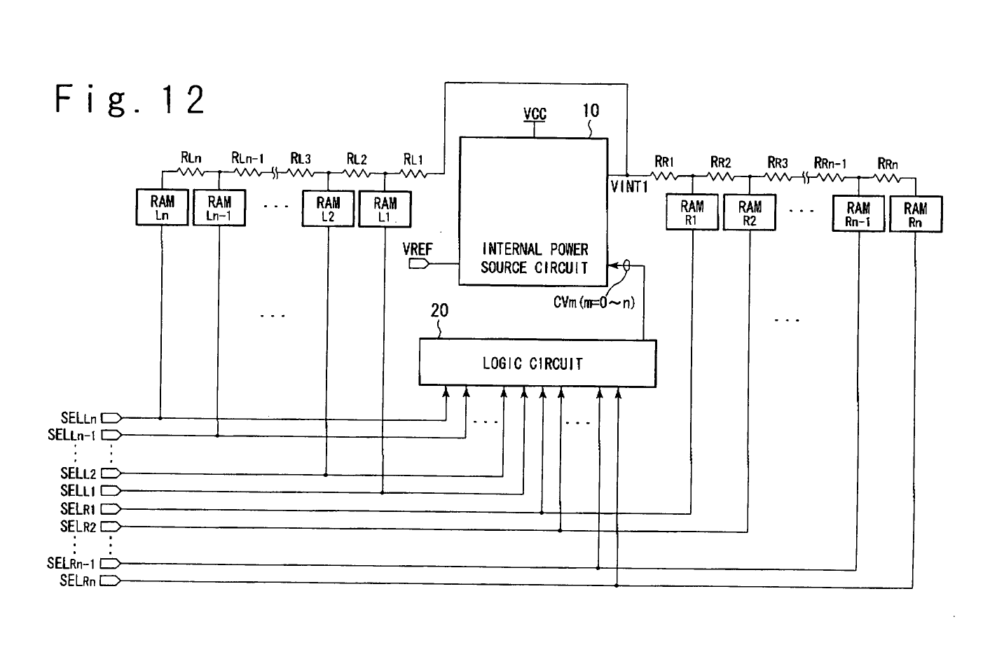

FIG. 12 is a view showing a configuration of the semiconductor integrated circuit device according to the third embodiment of the present invention. The RAM circuit in this semiconductor integrated circuit device is roughly divided into two portions and arranged, as the plurality of RAM circuit blocks. This RAM circuit is divided into: n number of RAM circuit blocks RAMR1 to RAMRn (n is the integer) in one group; and n number of RAM circuit blocks RAML1 to RAMLn in a second group.

It is assumed that the n number of the RAM circuit blocks RAMR1 to RAMRn in the first group are arranged in the order starting with the first RAM circuit block RAMR1 closest to the internal power source circuit 10 to the n-th RAM circuit block RAMRn. Similarly, it is assumed that the n number of the RAM circuit blocks RAML1 to RAMLn in the second group are arranged in the order starting with the first RAM circuit block RAML1 closest to the internal power source circuit 10 to the n-th RAM circuit block RAMLn. The internal power source wiring is connected to the internal power source circuit 10. The internal power source wiring is laid out from the internal power source circuit 10 and then branched as the first and second internal power source wirings. The first and second internal power source wirings are laid out in the first and second groups, respectively. It is assumed that the internal power source wiring is laid out at the relatively low resistance between the internal power source circuit 10 and the branch point, as compared with the parasitic resistance on and after the branch point.

The n number of the RAM circuit blocks RAMR1 to RAMRn in the first group are connected to the first internal power source wiring in parallel. In the first internal power source wiring, n number of parasitic resistances RR1 to RRn arise as the parasitic resistances that correspond to the arrangement places of the n number of the RAM circuit blocks RAMR1 to RAMRn in the first group, respectively. That is, the n number of the RAM circuit blocks RAMR1 to RAMRn in the first group are connected through n number of power source ports to the first internal power source wiring, respectively. The n parasitic resistances RR1 to RRn corresponding to the n number of the RAM circuit blocks RAMR1 to RAMRn in the first group are generated between the power source ports of the first internal power source wiring, respectively. In order to simplify the explanation, all of the resistance values of then number of the parasitic resistances RR1 to RRn are assumed to be equal.

The n number of the RAM circuit blocks RAML1 to RAMLn in the second group are connected to the second internal power source wiring in parallel. In the second internal power source wiring, n number of parasitic resistances RL1 to RLn arise as the parasitic resistances that correspond to the arrangement places of the n number of the RAM circuit blocks RAML1 to RAMLn in the second group, respectively. That is, the n number of the RAM circuit blocks RAML1 to RAMLn in the second group are connected through n number of power source ports to the second internal power source wiring, respectively. The n number of the parasitic resistances RL1 to RLn corresponding to the n number of the RAM circuit blocks RAML1 to RAMLn in the second group are generated between the power source ports of the second internal power source wiring, respectively. In order to simplify the explanation, all of the resistance values of the n number of the parasitic resistances RL1 to RLn are assumed to be equal.

Here, n number of signal lines for supplying RAM circuit block activation signals SELR1 to SELRn are connected to the n number of the RAM circuit blocks RAMR1 to RAMRn in the first group. The n number of the signal lines are also connected to the inputs of the logic circuit 20. Similarly, n number of signal lines for supplying RAM circuit block activation signals SELL1 to SELLn are connected to the n number of the RAM circuit blocks RAML1 to RAMLn in the second group, respectively. The n number of the signal lines are also connected to the inputs of the logic circuit 20. The logic circuit 20 supplies the voltage division control signal CVm (m is the integer satisfying 0 to n) to the voltage dividing circuit 13, by using the RAM circuit block activation signals SELR1 to SELRn and SELL1 to SELLn.

For example, the n number of the RAM circuit blocks RAMR1 to RAMRn in the first group correspond to the n number of the RAM circuit blocks RAM1 to RAMn in the first and second embodiments, and the RAM circuit block activation signals SELR1 to SELRn correspond to the RAM circuit block activation signals SEL1 to SELn in the first and second embodiments.

Similarly, the n number of the RAM circuit blocks RAML1 to RAMLn in the second group correspond to the n number of the RAM circuit blocks RAM1 to RAMn in the first and second embodiments, and the RAM circuit block activation signals SELL1 to SELLn correspond to the RAM circuit block activation signals SEL1 to SELn in the first and second embodiments.

### [Operation]

An operation of the semiconductor integrated circuit device according to the third embodiment of the present invention is described with regard to the case in which the two RAM circuit blocks currently in operation exist at the same time, in order to simplify the description. Here, the operation current of one RAM circuit block is defined as Iact.

In order to select the RAM circuit blocks RAMR1, RAML1, the signal levels of the RAM circuit block activation signals SELR1, SELL1 are switched to the high level “H”. At this time, the RAM circuit blocks RAMR1, RAML1 are made active.

On the basis of the operation current Iact of the selected RAM circuit blocks RAMR1, RAML1 and the parasitic resistances RR1, RL1 in the internal power source wirings between the internal power source circuit 10 and the power source ports of the respective RAM circuit blocks RAMR1, RAML1, the drop compensation amounts of the respective internal power source voltages are (Iact×RR1) on the side of the RAM circuit block RAMR1 and (Iact×RL1) on the side of the RAM circuit block RAML1.

Here, the RAM circuit blocks operated at the same time are laid out such that the parasitic resistances of the internal power source wirings are equal. Preferably, they are laid out such that the voltage drop amounts are equal. Or, they may be selectively operated such that the RAM circuit blocks in which the parasitic resistances of the internal power source wirings are equal are operated at the same time. Such configuration can simplify the drop compensation control for the output voltage of the internal power source circuit.

In this way, in the third embodiment, with consideration for the drop compensation amount for the output voltage VINT1′ of the internal power source circuit 10, the output voltage VINT1′ is controlled to VINT1+(Iact×RL1), which is equal to VINT1+(Iact×RR1). Thus, when the plurality of RAM circuit blocks RAMR1, RAML1 are selected at the same time, the voltages applied to the power source ports of the respective RAM circuit blocks RAMR1, RAML1 can be made equal.

Also, the third embodiment is described by exemplifying the RAM circuit blocks RAMR1, RAML1 closest to the internal power source circuit 10. However, even if the RAM circuit blocks RAMRn, RAMLn farthest from the internal power source circuit 10 are operated at the same time, similarly, the voltage applied to the power source ports of the respective RAM circuit blocks can be made equal.

Also, in the third embodiment, since the RAM circuit blocks operated at the same time are dispersedly arranged in the internal power source wirings belonging to the different systems, the operation currents of the RAM circuit blocks flowing through one system are minimized, thereby suppressing the drop in the internal power source voltage generated in the circuit operation. In the case of the content based on this principle, it can be applied to, for example, the layout in which the RAM circuit is divided into the three groups or more, other than the embodiment of the layout in which the RAM circuit is divided into the two groups as mentioned here.

### [Effect]

The effect of the semiconductor integrated circuit device according to the third embodiment of the present invention will be described below.

According to the semiconductor integrated circuit device according to the third embodiment of the present invention, the RAM circuit includes the plurality of groups; each group includes the plurality of RAM circuit blocks RAM1 to RAMn in the first and second embodiments. For example, the RAM circuit includes the RAM circuit blocks RAMR1 to RAMRn which are the RAM circuit blocks RAM1 to RAMn in the first group; and the RAM circuit blocks RAML1 to RAMLn which are the RAM circuit blocks RAM1 to RAMn in the second group. The RAM circuit blocks RAMR1 to RAMRn in the first group are arranged in the order, which starts with the RAM circuit block RAMR1 closest to the internal power source circuit 10 and ends with the RAM circuit block RAMRn farthest from the internal power source circuit 10. Similarly, the RAM circuit blocks RAML1 to RAMLn in the second group are arranged in the order, which starts with the RAM circuit block RAML1 closest to the internal power source circuit 10 and ends with the RAM circuit block RAMLn farthest from the internal power source circuit 10. In the internal power source wiring, the parasitic resistances RR1 to RRn are generated respectively correspondingly to the arrangement places of the RAM circuit blocks RAMR1 to RAMRn in the first group. Also, in the internal power source wiring, the parasitic resistances RL1 to RLn are generated respectively correspondingly to the arrangement places of the RAM circuit blocks RAML1 to RAMLn in the second group. The selection RAM circuit block includes at least one RAM circuit block among the RAM circuit blocks RAMR1 to RAMRn in the first group; and at least one RAM circuit block among the RAM circuit blocks RAML1 to RAMLn in the second group. Thus, according to the semiconductor integrated circuit device according to the third embodiment of the present invention, as its effect, it is possible to decrease the operation current of the RAM circuit block and the parasitic resistance of the internal power source wiring.

The semiconductor integrated circuit device according to the third embodiment of the present invention is described with regard to the method in which the output voltage VINT1′ of the internal power source circuit 10 is controlled at the n steps on the basis of the selection RAM circuit block for the n number of the RAM circuit blocks provided in the LCD driver. However, it is not limited to this case. As the variation example of the semiconductor integrated circuit device according to the third embodiment of the present invention, the number of the control steps may be reduced within the ranges of the allowable internal power source voltage and the allowable access speed (this fact is already described in FIG. 10).

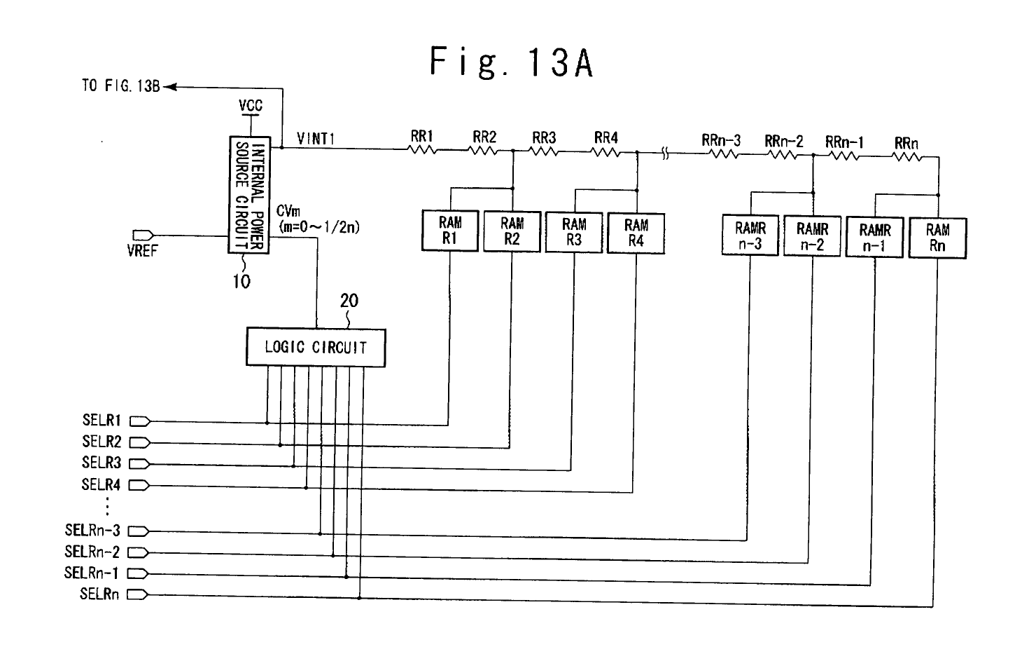

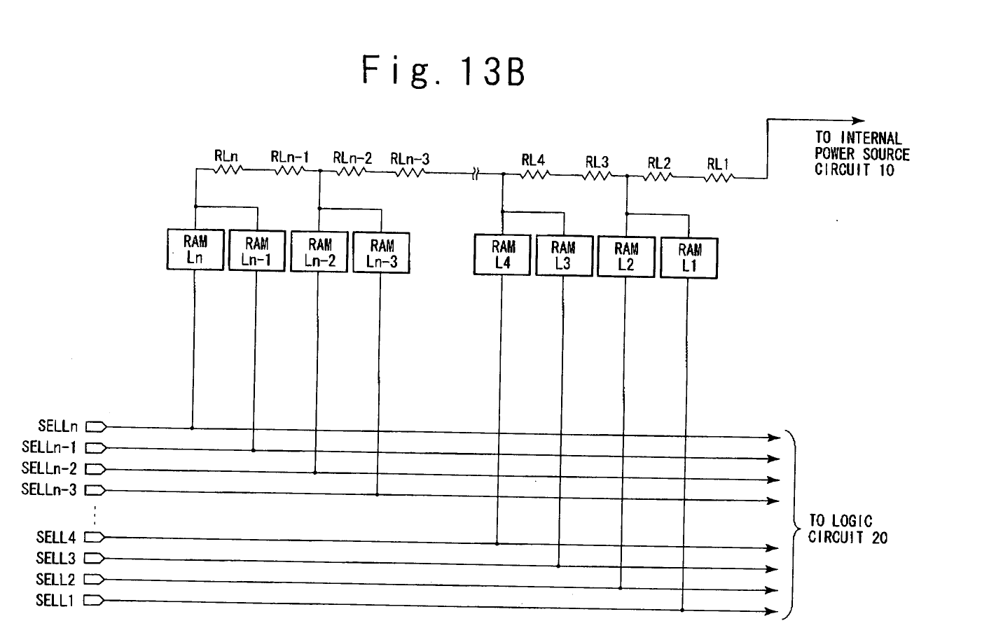

FIGS. 13A and 13B are views showing a configuration of a variation example 1 of the semiconductor integrated circuit device according to the third embodiment of the present invention.

In the variation example 1 of the semiconductor integrated circuit device according to the third embodiment of the present invention, the RAM circuit includes the plurality of groups; each group includes the plurality of RAM circuit blocks RAM1 to RAM2, - - - , and RAMn−1 to RAMn in the variation example 1 of the first embodiment. For example, the RAM circuit includes: the RAM circuit blocks RAMR1 to RAMR2, - - - , and RAMRn−1 to RAMRn that are the RAM circuit blocks RAM1 to RAM2, - - - , and RAMn−1 to RAMn in the first group; and the RAM circuit blocks RAML1 to RAML2, - - - , and RAMLn−1 to RAMLn that are the RAM circuit blocks RAM1 to RAM2, - - - , and RAMn−1 to RAMn in the second group. The RAM circuit blocks RAMR1 to RAMR2, - - - , and RAMRn−1 to RAMRn in the first group are arranged in the order, which starts with the RAM circuit block RAMR1 closest to the internal power source circuit 10 and ends with the RAM circuit block RAMRn farthest from the internal power source circuit 10. Similarly, the RAM circuit blocks RAML1 to RAML2, - - - , and RAMLn−1 to RAMLn in the second group are arranged in the order, which starts with the RAM circuit block RAML1 closest to the internal power source circuit 10 and ends with the RAM circuit block RAMLn farthest from internal power source circuit 10. In the internal power source wiring, the parasitic resistances RR1 to RR2, and RRn−1 to RRn are generated respectively correspondingly to the arrangement places of the RAM circuit blocks RAMR1 to RAMR2, - - - , and RAMRn−1 to RAMRn in the first group. Similarly, in the other internal power source wiring, the parasitic resistances RL1 to RL2, - - - , and RLn−1 to RLn are generated respectively correspondingly to the arrangement places of the RAM circuit blocks RAML1 to RAML2, - - - , and RAMLn−1 to RAMLn in the second group. The selection RAM circuit block includes at least one RAM circuit block among the RAM circuit blocks RAMR1 to RAMR2, - - - , and RAMRn−1 to RAMRn in the first group; and at least one RAM circuit block among the RAM circuit blocks RAML1 to RAML2, - - - , and RAMLn−1 to RAMLn in the second group.

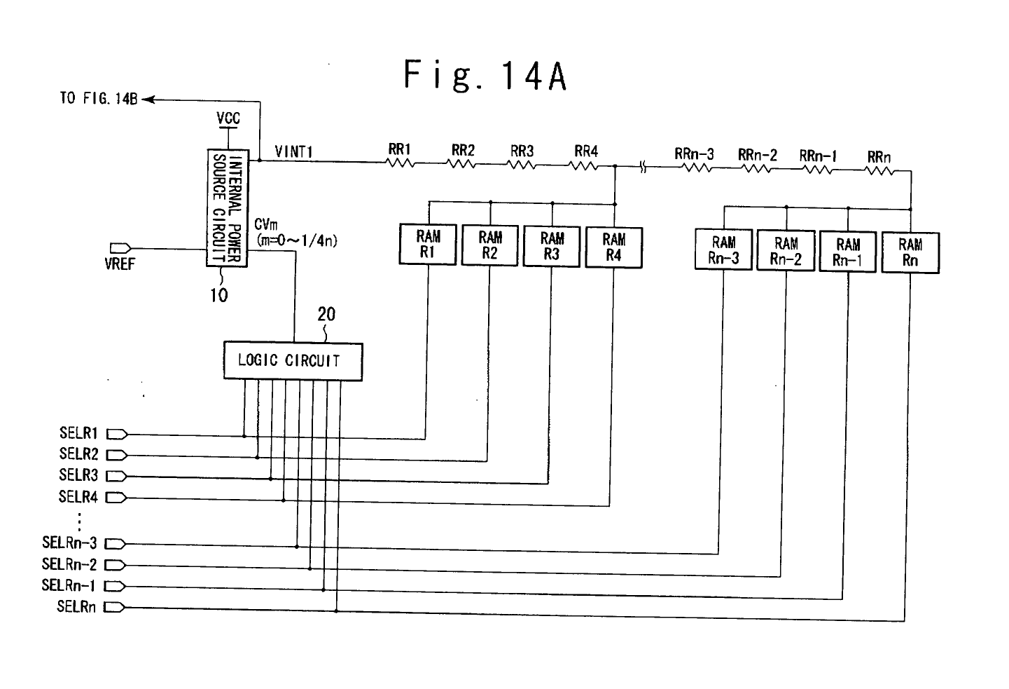

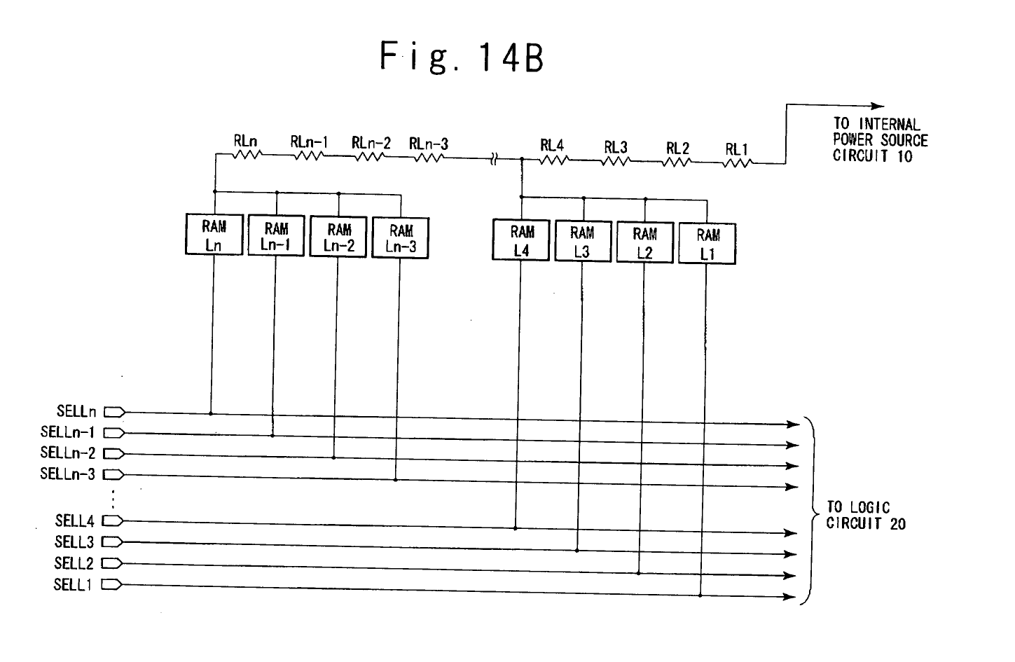

FIGS. 14A and 14B are views showing a configuration of a variation example 2 of the semiconductor integrated circuit device according to the third embodiment of the present invention.

In the variation example 2 of the semiconductor integrated circuit device according to the third embodiment of the present invention, the RAM circuit includes the plurality of groups; each group includes the plurality of RAM circuit blocks RAM1 to RAM4, - - - , and RAMn−3 to RAMn in the variation example 2 of the first embodiment. For example, the RAM circuit includes: the RAM circuit blocks RAMR1 to RAMR4, - - - , and RAMRn−3 to RAMRn that are the RAM circuit blocks RAM1 to RAM4, - - - , and RAMn−3 to RAMn in the first group; and the RAM circuit blocks RAML1 to RAML4, - - - , and RAMLn−3 to RAMLn that are the RAM circuit blocks RAM1 to RAM4, - - - , and RAMn−3 to RAMn in the second group. The RAM circuit blocks RAMR1 to RAMR4, - - - , and RAMRn−3 to RAMRn in the first group are arranged in the order, which starts with the RAM circuit block RAMR1 closest to the internal power source circuit 10 and ends with the RAM circuit block RAMRn farthest from the internal power source circuit 10. Similarly, the RAM circuit blocks RAML1 to RAML4, - - - , and RAMLn−3 to RAMLn in the second group are arranged in the order, which starts with the RAM circuit block RAML1 closest to the internal power source circuit 10 and ends with the RAM circuit block RAMLn farthest from the internal power source circuit 10. In the internal power source wiring, the parasitic resistances RR1 to RR4, - - - , and RRn−3 to RRn are generated respectively correspondingly to the arrangement places of the RAM circuit blocks RAMR1 to RAMR4, - - - , and RAMRn−3 to RAMRn in the first group. Similarly, in the other internal power source wiring, the parasitic resistances RL1 to RL4, - - - , and RLn−3 to RLn are generated respectively correspondingly to the arrangement places of the RAM circuit blocks RAML1 to RAML4, - - - , and RAMLn−3 to RAMLn in the second group. The selection RAM circuit block includes at least one RAM circuit block among the RAM circuit blocks RAMR1 to RAMR4, - - - , and RAMRn−3 to RAMRn in the first group; and at least one RAM circuit block among the RAM circuit blocks RAML1 to RAML4, and RAMLn−3 to RAMLn in the second group.

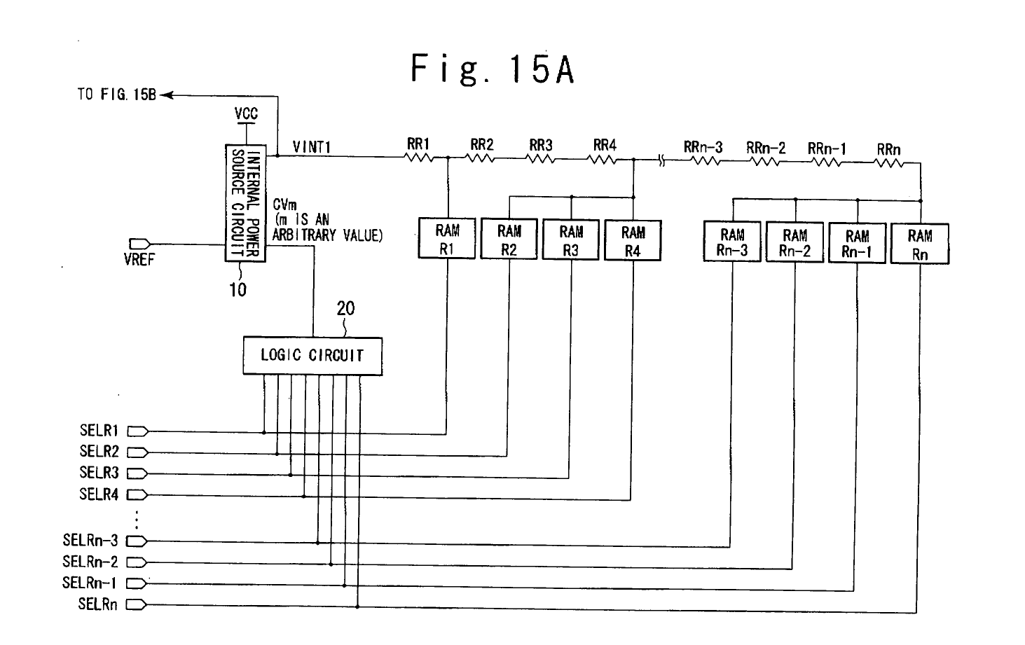

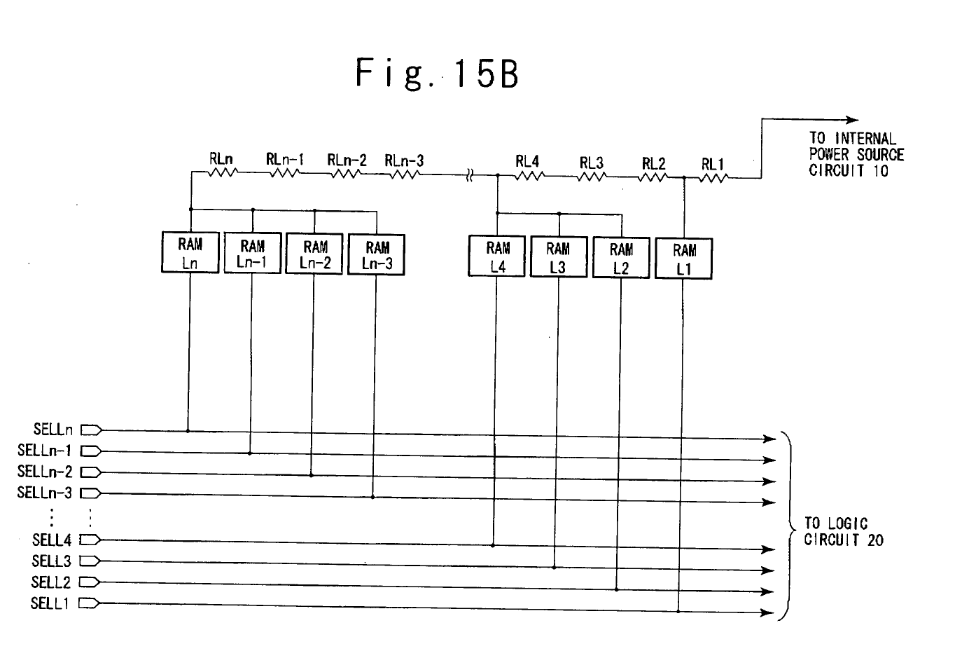

FIGS. 15A and 15B are views showing a configuration of a variation example 3 of the semiconductor integrated circuit device according to the third embodiment of the present invention.

In the variation example 3 of the semiconductor integrated circuit device according to the third embodiment of the present invention, the RAM circuit includes the plurality of groups; each group includes the plurality of RAM circuit blocks RAM1, RAM2 to RAM4, - - - , and RAMn−3 to RAMn in the variation example 3 of the first embodiment. For example, the RAM circuit includes: the RAM circuit blocks RAMR1, RAMR2 to RAMR4, - - - , and RAMRn−3 to RAMRn that are the RAM circuit blocks RAM1, RAM2 to RAM4, - - - , and RAMn−3 to RAMn in the first group; and the RAM circuit blocks RAML1, RAML2 to RAML4, - - - , and RAMLn−3 to RAMLn that are the RAM circuit blocks RAM1, RAM2 to RAM4, and RAMn−3 to RAMn in the second group. The RAM circuit blocks RAMR1, RAMR2 to RAMR4, - - - , and RAMRn−3 to RAMRn in the first group are arranged in the order, which starts with the RAM circuit block RAMR1 closest to the internal power source circuit 10 and ends with the RAM circuit block RAMRn farthest from the internal power source circuit 10. Similarly, the RAM circuit blocks RAML1, RAML2 to RAML4, - - - , and RAMLn−3 to RAMLn in the second group are arranged in the order, which starts with the RAM circuit block RAML1 closest to the internal power source circuit 10 and ends with the RAM circuit block RAMLn farthest from the internal power source circuit 10. In the internal power source wiring, the parasitic resistances RR1, RR2 to RR4, - - - , and RRn−3 to RRn are generated respectively correspondingly to the arrangement places of the RAM circuit blocks RAMR1, RAMR2 to RAMR4, - - - , and RAMRn−3 to RAMRn in the first group. Similarly, in the other internal power source wiring, the parasitic resistances RL1, RL2 to RL4, - - - , and RLn−3 to RLn are generated respectively correspondingly to the arrangement places of the RAM circuit blocks RAML1, RAML2 to RAML4, - - - , and RAMLn−3 to RAMLn in the second group. The selection RAM circuit block includes at least one RAM circuit block among the RAM circuit blocks RAMR1, RAMR2 to RAMR4, - - - , and RAMRn−3 to RAMRn in the first group; and at least one RAM circuit block among the RAM circuit blocks RAML1, RAML2 to RAML4, - - - , and RAMLn−3 to RAMLn in the second group.

Also, in the semiconductor integrated circuit devices according to the first to third embodiments of the present invention, the RAM circuit blocks of the same kind are used. However, they are not limited to this case. Even in the case of using different kinds of circuit blocks, the present invention can be applied. Also, different kinds of circuit blocks may be mixed. In this case, although the operation currents differ from each other, the present invention can be applied along the principle of controlling the internal power source voltage VINT1 outputted from the internal power source circuit 10 based on the drop amount of the internal power source voltage.

Also, in the semiconductor integrated circuit devices according to the first to third embodiments of the present invention, the method of controlling the output voltage VINT1′ by changing the voltage division ratio is described as the control manner of the output voltage VINT1′ of the internal power source circuit 10. However, the other circuit configurations and control methods may be used.

Also, in the semiconductor integrated circuit devices according to the first to third embodiments of the present invention, the period in which the output voltage VINT1′ of the internal power source circuit 10 is controlled to be high is described in the period in which the RAM circuit block activation signal is at the high level “H”. However, there is a circuit in which the operation is continued for a while, even if the activation signal is turned off, depending on the circuit. Thus, when the present invention is applied to the foregoing circuit, in the period while the circuit is active, the internal power source circuit 10 should set the control period in which the internal power source voltage VINT1 is controlled to be high.

Also, the semiconductor integrated circuit devices according to the first to third embodiments of the present invention are described from the viewpoint in which the internal power source voltage is maintained similarly to the output voltage of the internal power source circuit. However, the output voltage of the internal power source circuit may be controlled to be high, in such a way that the voltage applied to the power source port becomes higher, even if the voltage drop is considered for the necessary circuit block, depending on the operation state.

Also, in the semiconductor integrated circuit devices according to the first to third embodiments of the present invention, the present invention is described exemplifying the RAM circuit block provided in the LCD driver. However, if the object of improving the drop in the power source voltage that is caused by the parasitic resistance of the internal power source wiring is satisfied, the present invention can be applied to any semiconductor integrated circuit device.

Although the present invention has been described above in connection with several embodiments thereof, it would be apparent to those skilled in the art that those embodiments are provided solely for illustrating the present invention, and should not be relied upon to construe the appended claims in a limiting sense.

What is claimed is:

1. A semiconductor integrated circuit device, comprising:
a RAM (Random Access Memory) circuit configured to include a plurality of RAM circuit blocks; and
an internal power source circuit configured to supply a voltage to a selection RAM block selected from said plurality of RAM circuit blocks,
wherein said voltage corresponds to an arrangement place of said selection RAM circuit block.

2. The semiconductor integrated circuit device according to claim 1, further comprising:
an internal power source wiring configured to connect said internal power source circuit with said plurality of RAM circuit blocks,
wherein a plurality of parasitic resistances arises in said internal power source wiring correspondingly to a plurality of arrangement places of said plurality of RAM circuit blocks, respectively,
wherein a plurality of voltages corresponding to said plurality of parasitic resistances is set in said internal power source circuit for said plurality of RAM circuit block, respectively,
wherein said internal power source circuit supplies said voltage to said selection RAM circuit block, and
said voltage is included in said plurality of voltages, and corresponds to said arrangement place of said selection RAM circuit block in said plurality of arrangement places.

3. The semiconductor integrated circuit device according to claim 2, wherein said internal power source circuit includes:
a voltage dividing circuit configured to have a plurality of voltage division ratios to set said plurality of voltages,
wherein said plurality of voltage division ratios corresponds to said plurality of RAM circuit blocks, respectively,
wherein said internal power source circuit selects a selection voltage division ratio corresponding to said selection RAM circuit block from said plurality of voltage division ratios, and supplies said voltage to said selection RAM circuit block, and
said voltage corresponds to said selection voltage division ratio.

4. The semiconductor integrated circuit device according to claim 3, further comprising;
a logic circuit configured to output a division control signal for selecting said selection voltage division ratio to said voltage dividing circuit, based on a RAM circuit block activation signal for selecting said selection RAM circuit block,
wherein said voltage dividing circuit selects said selection voltage division ratio from said plurality of voltage division ratios based on said division control signal, and
wherein said internal power source circuit supplies said voltage corresponding to said selection voltage division ratio to said selection RAM circuit block.

5. The semiconductor integrated circuit device according to claim 2, wherein said internal power source circuit generates an internal power source voltage,
wherein said plurality of RAM circuit blocks are connected to said internal power source wiring in parallel,
wherein when each of said plurality of RAM circuit block is selected and operated, a drop voltage are generated based on an operation current of said each RAM circuit block and parasitic resistance between said each RAM circuit block and said internal power source circuit with respect to said each RAM circuit block, and
wherein each of said plurality of voltage is the sum of said internal power source voltage and said drop voltage with respect to said each RAM circuit block.

6. The semiconductor integrated circuit device according to claim 5, wherein when said plurality of RAM circuit block is represented as n number of RAM circuit blocks from a first RAM circuit block to a n-th (n is an integer) RAM circuit block,
said plurality of parasitic resistances corresponding to said n number of RAM circuit blocks is represented as R1, R1+R2, - - - , and R1+ - - - +Rn,
an operation current of each of said n number of RAM circuit block is represented as Iact,
said internal power source voltage is represented as VINT1,
said selection RAM circuit block is represented as a j-th RAM circuit block (j is an integer, equal to or larger than 1, and equal to or smaller than n), and
said output voltage is represent as VINT1′, which is a voltage in said plurality of voltage corresponding to said j-th RAM circuit block,
said VINT1′ is represented by an equation of:
$$VINT {1}^{′} = VINT 1 + ( Iact \times {\sum }_{i = 1}^{j} Ri ) \qquad$$
said i is an integer, equal to or larger than 1, and equal to or smaller than n.

7. The semiconductor integrated circuit device according to claim 2, wherein said plurality of RAM circuit blocks is arranged in the order which starts from a RAM circuit block with the lowest parasitic resistance and ends with a RAM circuit block with the greatest parasitic resistance.

8. The semiconductor integrated circuit device according to claim 1, further comprising:
an internal power source wiring configured to connect said internal power source circuit with said plurality of RAM circuit blocks,
wherein when said plurality of RAM circuit block is n number of RAM circuit blocks from a first RAM circuit block to a n-th (n is an integer) RAM circuit block,
wherein said n number of RAM circuit blocks constitute x number of RAM circuit block groups (x is an integer, less than n),
wherein a plurality of parasitic resistances arises in said internal power source wiring correspondingly to a plurality of arrangement places of said x number of RAM circuit block groups, respectively,
wherein x number of voltages corresponding to said plurality of parasitic resistances is set in said internal power source circuit for said x number of RAM circuit block groups, respectively,
wherein said internal power source circuit supplies said voltage to said selection RAM circuit block, and
said voltage is included in said x number of voltages, and corresponds to said arrangement place of said selection RAM circuit block in said plurality of arrangement places.

9. The semiconductor integrated circuit device according to claim 8, wherein the number of RAM circuit blocks in each of said x number of RAM circuit block groups is N, N is an integer which satisfies an equation of n=x×N.

10. The semiconductor integrated circuit device according to claim 8, wherein said internal power source circuit includes:
a voltage dividing circuit configured to have x number of voltage division ratios to set said x number of voltages,
wherein said x number of voltage division ratios corresponds to said x number of RAM circuit blocks, respectively,
wherein said internal power source circuit selects a selection voltage division ratio corresponding to said selection RAM circuit block from said x number of voltage division ratios, and supplies said voltage to said selection RAM circuit block, and
said voltage corresponds to said selection voltage division ratio.

11. The semiconductor integrated circuit device according to claim 10, further comprising:
a logic circuit configured to output a division control signal for selecting said selection voltage division ratio to said voltage dividing circuit based on a RAM circuit block activation signal for selecting said selection RAM circuit block,
wherein said voltage dividing circuit selects said selection voltage division ratio from said x number of voltage division ratios based on said division control signal, and
wherein said internal power source circuit supplies said voltage corresponding to said selection voltage division ratio to said selection RAM circuit block.

12. The semiconductor integrated circuit device according to claim 8, wherein said plurality of RAM circuit blocks is arranged in the order which starts from a RAM circuit block with the lowest parasitic resistance and ends with a RAM circuit block with the greatest parasitic resistance.

13. The semiconductor integrated circuit device according to claim 1, wherein said plurality of RAM circuit blocks is arranged in the order which starts from a RAM circuit block closest to said internal power source circuit and ends with a RAM circuit block farthest from said internal power source circuit.

14. The semiconductor integrated circuit device according to claim 1, wherein said selection RAM circuit block is two or more of said plurality of RAM circuit blocks.

15. The semiconductor integrated circuit device according to claim 1, wherein said RAM circuit includes a plurality of groups, each of said plurality of groups includes said plurality of RAM circuit blocks,
wherein said selection RAM circuit block includes:
at least one of RAM circuit block for each of said plurality of groups.

16. A liquid crystal display driver for driving a liquid crystal display panel, comprising:
a RAM (Random Access Memory) circuit configured to include a plurality of RAM circuit blocks; and
an internal power source circuit configured to supply a voltage to a selection RAM block selected from said plurality of RAM circuit blocks,
wherein said voltage corresponds to an arrangement place of said selection RAM circuit block.

17. The liquid crystal display driver according to claim 16, further comprising:
an internal power source wiring configured to connect said internal power source circuit with said plurality of RAM circuit blocks,
wherein a plurality of parasitic resistances arises in said internal power source wiring correspondingly to a plurality of arrangement places of said plurality of RAM circuit blocks, respectively,
wherein a plurality of voltages corresponding to said plurality of parasitic resistances is set in said internal power source circuit for said plurality of RAM circuit block, respectively,
wherein said internal power source circuit supplies said voltage to said selection RAM circuit block, and
said voltage is included in said plurality of voltages, and corresponds to said arrangement place of said selection RAM circuit block in said plurality of arrangement places.

18. The liquid crystal display driver according to claim 16, further comprising:
an internal power source wiring configured to connect said internal power source circuit with said plurality of RAM circuit blocks,
wherein when said plurality of RAM circuit block is n number of RAM circuit blocks from a first RAM circuit block to a n-th (n is an integer) RAM circuit block,
wherein said n number of RAM circuit blocks constitute x number of RAM circuit block groups (x is an integer, less than n),
wherein a plurality of parasitic resistances arises in said internal power source wiring correspondingly to a plurality of arrangement places of said x number of RAM circuit block groups, respectively,
wherein x number of voltages corresponding to said plurality of parasitic resistances is set in said internal power source circuit for said x number of RAM circuit block groups, respectively,
wherein said internal power source circuit supplies said voltage to said selection RAM circuit block, and
said voltage is included in said x number of voltages, and corresponds to said arrangement place of said selection RAM circuit block in said plurality of arrangement places.
